(19) United States
(12) Patent Application Publication
(10) Pub. No.: US 2022/0187709 A1
(43) Pub. Date: Jun. 16, 2022

(54) FILM-FORMING COMPOSITION

(71) Applicant: NISSAN CHEMICAL CORPORATION, Tokyo (JP)

(72) Inventors: Wataru SHIBAYAMA, Toyama-shi (JP); Satoshi TAKEDA, Toyama-shi (JP); Shuhei SHIGAKI, Toyama-shi (JP); Ken ISHIBASHI, Toyama-shi (JP); Kodai KATO, Toyama-shi (JP); Makoto NAKAJIMA, Toyama-shi (JP)

(73) Assignee: NISSAN CHEMICAL CORPORATION, Tokyo (JP)

(21) Appl. No.: 17/598,955

(22) PCT Filed: Mar. 24, 2020
(86) PCT No.: PCT/JP2020/013162

§ 371 Date: Sep. 28, 2021

(30) Foreign Application Priority Data
Mar. 28, 2019 (JP) 2019-063792

(51) Int. Cl. G03F 7/11; C08G 77/26; C09D 183/08; H01L 21/027

(52) U.S. Cl. CPC G03F 7/11; H01L 21/0274; C09D 183/08; C08G 77/26

(57) ABSTRACT

A film-forming composition including one selected from among a hydrolyzable silane compound, a hydrolysate of the compound, and a hydrolysis condensate of the compound, and a solvent, the film-forming composition wherein: the hydrolyzable silane compound contains a hydrolyzable silane having a cyano group in the molecule and being of the following Formula (1):

R¹ₐR²_{b}Si(R³)_{4-(a+b)} (1)

(wherein R¹ is a group bonded to a silicon atom and is an organic group containing a cyano group; R² is a group bonded to a silicon atom via an Si—C bond, and is each independently a substitutable alkyl group, etc.; R³ is a group or atom bonded to a silicon atom, and is each independently a hydroxy group, an alkoxy group, an aralkyloxy group, an acyloxy group, or a halogen atom; a is an integer of 1; b is an integer of 0 to 2; and a+b is an integer of 1 to 3).

### TECHNICAL FIELD

The present invention relates to a film-forming composition.

### BACKGROUND ART

In the field of production of semiconductor devices, a technique has been widely used in which a fine pattern is formed on a substrate, and the substrate is processed through etching in accordance with the pattern.

The progress of lithography technology has led to fine patterning, and studies have been conducted on light exposure techniques using KRF excimer laser, ARF excimer laser, electron beams, and EUV (extreme ultraviolet rays).

In a fine processing process by lithography using a photoresist, a photoresist thin film is formed on a semiconductor substrate (e.g., a silicon wafer); the thin film is irradiated with active rays (e.g., ultraviolet rays) through a mask pattern having a semiconductor device pattern drawn thereon; the irradiated thin film is developed; and the substrate is etched with the resultant photoresist pattern serving as a protective film, to thereby form, on the surface of the substrate, fine irregularities corresponding to the pattern. In recent years, active rays having a shorter wavelength have tended to be used as described above in association with an increase in the degree of integration of semiconductor devices. This tendency causes a serious problem in terms of the influence of reflection of active rays from a semiconductor substrate. Under such circumstances, there has been widely used a method involving disposing a resist underlayer film called “bottom anti-reflective coating (BARC)” between a photoresist and a substrate to be processed.

The progress of fine resist patterning may cause problems in terms of resolution, dimensional accuracy, and pattern collapse, and thus demand has arisen for thinning of a resist. Therefore, difficulty is encountered in achieving a resist pattern thickness sufficient for processing of a substrate, and a process is required for imparting a mask function (during processing of the substrate) not only to a resist pattern, but also to a resist underlayer film formed between the resist and the semiconductor substrate to be processed. Further progress of fine resist patterning has led to application of a tri-layer process for forming a silicon-containing resist underlayer film (intermediate layer) below a resist film (upper layer), and an organic underlayer film (lower layer) below the silicon-containing resist underlayer film.

In recent years, resist films have been significantly thinned and fined in state-of-the-art semiconductor devices. In particular, the aforementioned tri-layer (including a resist film, a silicon-containing resist underlayer film, and an organic underlayer film) process requires lithographic properties of the resist on the silicon-containing resist underlayer film, as well as high etching rate of the underlayer film. In particular, an EUV lithography requires introduction of a large amount of a functional group exhibiting high adhesion to a resist film for improving lithographic properties, and addition of a large amount of a photoacid generator for improving resolution. However, an increase in the amount of such an organic component causes a serious problem in terms of a reduction in etching rate. Thus, there has conventionally been a trade-off relationship between an improvement in lithographic properties and achievement of high etching rate.

Under such circumstances, there have been reported a resist underlayer film-forming composition containing a silane compound having an onium group, and a resist underlayer film containing a silane compound having an anionic group (Patent Documents 1 and 2).

### PRIOR ART DOCUMENTS

### Patent Documents

Patent Document 1: International Publication WO 2010/021290

Patent Document 2: International Publication WO 2010/071155

### SUMMARY OF THE INVENTION

### Problems to be Solved by the Invention

In view of the above-described circumstances, an object of the present invention is to provide a film-forming composition suitable as a resist underlayer film-forming composition capable of forming a resist underlayer film that exhibits favorable adhesion to an EUV resist and favorable etching processability.

### Means for Solving the Problems

In order to achieve the aforementioned object, the present inventors have focused on a curable system not containing a curing catalyst as an additive, and have conducted extensive studies on a silicon-containing underlayer film having a polymer skeleton provided with a catalytic function. As a result, the present inventors have found that a thin film exhibiting favorable adhesion to an EUV resist, being capable of forming an excellent resist pattern when used as an underlayer film of the EUV resist, and exhibiting favorable dry etching processability can be formed from a film-forming composition containing at least one selected from among a hydrolyzable silane having a cyano group in the molecule, a hydrolysate of the silane, and a hydrolysis condensate of the silane, and a solvent. The present invention has been accomplished on the basis of this finding.

Accordingly, a first aspect of the present invention is a film-forming composition comprising at least one selected from among a hydrolyzable silane compound, a hydrolysate of the compound, and a hydrolysis condensate of the compound, and a solvent, the film-forming composition being characterized in that:

the hydrolyzable silane compound contains a hydrolyzable silane having a cyano group in the molecule and being of the following Formula (1):

R¹ₐR²_{b}Si(R³)_{4-(a+b)} (1)

(wherein R¹ is a group bonded to a silicon atom and is an organic group containing a cyano group;

R² is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these;

R³ is a group or atom bonded to a silicon atom, and is each independently a hydroxy group, an alkoxy group, an aralkyloxy group, an acyloxy group, or a halogen atom;

a is an integer of 1;

b is an integer of 0 to 2; and

a+b is an integer of 1 to 3).

A second aspect of the present invention is the film-forming composition according to the first aspect, wherein the organic group containing a cyano group is an organic group prepared by substitution of one or more hydrogen atoms of an alkyl group selected from the group consisting of a chain alkyl group, a branched alkyl group, and a cyclic alkyl group with a cyano-containing group selected from among a cyano group (—CN) and a thiocyanato group (—S—CN).

A third aspect of the present invention is the film-forming composition according to the first or second aspect, wherein the composition comprises a hydrolysis condensate of the hydrolyzable silane compound.

A fourth aspect of the present invention is the film-forming composition according to any one of the first to third aspects, wherein the hydrolyzable silane compound further contains at least one selected from among a hydrolyzable silane of the following Formula (2):

R⁴_{c}Si(R⁵)_{4-c} (2)

(wherein R⁴ is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these;

R⁵ is a group or atom bonded to a silicon atom, and is each independently an alkoxy group, an aralkyloxy group, an acyloxy group, or a halogen atom; and

c is an integer of 0 to 3), and a hydrolyzable silane of the following Formula (3):

[R⁶_{d}Si(R⁷)_{3-d}]₂Yₑ (3)

(wherein R⁶ is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these;

R⁷ is a group or atom bonded to a silicon atom, and is each independently an alkoxy group, an aralkyloxy group, an acyloxy group, or a halogen atom;

Y is a group bonded to a silicon atom via an Si—C bond, and is each independently an alkylene group or an arylene group;

d is an integer of 0 or 1; and

e is an integer of 0 or 1).

A fifth aspect of the present invention is the film-forming composition according to any one of the first to fourth aspects, wherein the hydrolysis condensate is a hydrolysis condensate of the hydrolyzable silane compound containing a hydrolyzable silane having a cyano group in the molecule and being of Formula (1) in an amount of 0.1% by mole to 10% by mole relative to the entire amount of the hydrolyzable silane compound.

A sixth aspect of the present invention is the film-forming composition according to any one of the first to fifth aspects, wherein hydrolysis of the hydrolyzable silane compound is performed with nitric acid serving as a hydrolysis catalyst.

A seventh aspect of the present invention is the film-forming composition according to any one of the first to sixth aspects, wherein the solvent contains water.

An eighth aspect of the present invention is the film-forming composition according to any one of the first to seventh aspects, wherein the composition further comprises a pH adjuster.

A ninth aspect of the present invention is the film-forming composition according to any one of the first to eighth aspects, wherein the composition further comprises a surfactant.

A tenth aspect of the present invention is the film-forming composition according to any one of the first to ninth aspects, wherein the composition is for forming a resist underlayer film for EUV lithography.

An eleventh aspect of the present invention is a resist underlayer film formed from the film-forming composition according to any one of the first to tenth aspects.

A twelfth aspect of the present invention is a semiconductor processing substrate comprising a semiconductor substrate and the resist underlayer film according to the eleventh aspect.

### Effects of the Invention

The present invention provides a film-forming composition containing at least one selected from among a hydrolyzable silane compound containing a hydrolyzable silane having a cyano group in the molecule and being of Formula (1), a hydrolysate of the compound, and a hydrolysis condensate of the compound, and a solvent. The composition can form a thin film exhibiting favorable adhesion to an EUV resist and favorable etching processability having a high rate of etching with fluorine.

Thus, the use of the film-forming composition of the present invention can form a thin film that achieves formation of a fine resist pattern and high transferability to an underlying substrate.

### Modes for Carrying Out the Invention

The present invention will next be described in more detail. The “solid content” of the film-forming composition of the present invention refers to all components (except for the solvent) contained in the composition.

As described below, the film-forming composition of the present invention contains at least one selected from among a specific hydrolyzable silane compound, a hydrolysate of the compound, and a hydrolysis condensate of the compound; i.e., the composition contains one, two, or three species of these. The hydrolysate or the hydrolysis condensate includes an incomplete hydrolysate (i.e., a partial hydrolysate) or a partial hydrolysis condensate.

The film-forming composition of the present invention contains at least one selected from among a hydrolyzable silane compound, a hydrolysate of the compound, and a hydrolysis condensate of the compound, and a solvent, and is characterized in that the hydrolyzable silane compound contains a hydrolyzable silane having a cyano group in the molecule.

[Hydrolyzable Silane Having Cyano Group in Molecule]

The hydrolyzable silane having a cyano group in the molecule and contained in the hydrolyzable silane compound used in the film-forming composition of the present invention is of the following Formula (1).

R¹ₐR²_{b}Si(R³)_{4-(a+b)} (1)

R¹ is a group bonded to a silicon atom and is an organic group containing a cyano group.

No particular limitation is imposed on the group, so long as it is an organic group containing a cyano group. Examples of the group include cyano-group-containing groups, such as a cyano group (—CN) or thiocyanato group (—SCN) itself, and in particular, an organic group prepared by substitution of one or more hydrogen atoms of an alkyl group with at least one or both of a cyano group (—CN) and a thiocyanato group (—SCN).

No particular limitation is imposed on the alkyl group wherein a hydrogen atom is substituted with the aforementioned cyano group or thiocyanato group. The alkyl group may be linear, branched, or cyclic, and the carbon atom number of the alkyl group may be generally 40 or less, for example, 30 or less, for example, 20 or less, or 10 or less.

Specific examples of the linear or branched alkyl group wherein a hydrogen atom can be substituted with the aforementioned cyano group or thiocyanato group include, but are not limited to, methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

Specific examples of the cyclic alkyl group wherein a hydrogen atom can be substituted with the aforementioned cyano group or thiocyanato group include, but are not limited to, cycloalkyl groups, such as cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl, and 2-ethyl-3-methyl-cyclopropyl group; and bicycloalkyl groups, such as bicyclobutyl group, bicyclopentyl group, bicyclohexyl group, bicycloheptyl group, bicyclooctyl group, bicyclononyl group, and bicyclodecyl group.

Among the aforementioned groups, R¹ may be, for example, a cyanoethyl group, a cyanobicycloheptyl group, or a thiocyanatopropyl group.

In Formula (1), R² is a group bonded to a silicon atom via an Si-C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these.

The aforementioned alkyl group may be, for example, a linear or branched alkyl group having a carbon atom number of 1 to 10. Examples of the alkyl group include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

The aforementioned alkyl group may be a cyclic alkyl group. Examples of the cyclic alkyl group having a carbon atom number of 1 to 10 include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

Examples of the aryl group include C₆₋₂₀ aryl groups, such as phenyl group, o-methylphenyl group, m-methylphenyl group, p-methylphenyl group, o-chlorophenyl group, m-chlorophenyl group, p-chlorophenyl group, o-fluorophenyl group, p-mercaptophenyl group, o-methoxyphenyl group, p-methoxyphenyl group, p-aminophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, and 9-phenanthryl group.

The aralkyl group is an alkyl group substituted with an aryl group, and specific examples of the aryl group and the alkyl group are the same as those described above.

No particular limitation is imposed on the carbon atom number of the aralkyl group, but the carbon atom number is preferably 40 or less, more preferably 30 or less, still more preferably 20 or less.

Specific examples of the aralkyl group include, but are not limited to, phenylmethyl group (benzyl group), 2-phenylethylene group, 3-phenyl-n-propyl group, 4-phenyl-n-butyl group, 5-phenyl-n-pentyl group, 6-phenyl-n-hexyl group, 7-phenyl-n-heptyl group, 8-phenyl-n-octyl group, 9-phenyl-n-nonyl group, and 10-phenyl-n-decyl group.

The halogenated alkyl group is an alkyl group substituted with a halogen atom.

Examples of the halogen atom include a fluorine atom, a chlorine atom, a bromine atom, and an iodine atom, and specific examples of the alkyl group are the same as those described above.

No particular limitation is imposed on the carbon atom number of the halogenated alkyl group, but the carbon atom number is preferably 40 or less, more preferably 30 or less, still more preferably 20 or less, much more preferably 10 or less.

Specific examples of the halogenated alkyl group include, but are not limited to, monofluoromethyl group, difluoromethyl group, trifluoromethyl group, bromodifluoromethyl group, 2-chloroethyl group, 2-bromoethyl group, 1,1-difluoroethyl group, 2,2,2-trifluoroethyl group, 1,1,2,2-tetrafluoroethyl group, 2-chloro-1,1,2-trifluoroethyl group, pentafluoroethyl group, 3-bromopropyl group, 2,2,3,3-tetrafluoropropyl group, 1,1,2,3,3,3-hexafluoropropyl group, 1,1,1,3,3,3-hexafluoropropan-2-yl group, 3-bromo-2-methylpropyl group, 4-bromobutyl group, and perfluoropentyl group.

The halogenated aryl group is an aryl group substituted with a halogen atom, and specific examples of the aryl group and the halogen atom are the same as those described above.

No particular limitation is imposed on the carbon atom number of the halogenated aryl group, but the carbon atom number is preferably 40 or less, more preferably 30 or less, still more preferably 20 or less.

Specific examples of the halogenated aryl group include, but are not limited to, 2-fluorophenyl group, 3-fluorophenyl group, 4-fluorophenyl group, 2,3-difluorophenyl group, 2,4-difluorophenyl group, 2,5-difluorophenyl group, 2,6-difluorophenyl group, 3,4-difluorophenyl group, 3,5-difluorophenyl group, 2,3,4-trifluorophenyl group, 2,3,5-trifluorophenyl group, 2,3,6-trifluorophenyl group, 2,4,5-trifluorophenyl group, 2,4,6-trifluorophenyl group, 3,4,5-trifluorophenyl group, 2,3,4,5-tetrafluorophenyl group, 2,3,4,6-tetrafluorophenyl group, 2,3,5,6-tetrafluorophenyl group, pentafluorophenyl group, 2-fluoro-1-naphthyl group, 3-fluoro-1-naphthyl group, 4-fluoro-1-naphthyl group, 6-fluoro-1-naphthyl group, 7-fluoro-1-naphthyl group, 8-fluoro-1-naphthyl group, 4,5-difluoro-1-naphthyl group, 5,7-difluoro-1-naphthyl group, 5,8-difluoro-1-naphthyl group, 5,6,7,8-tetrafluoro-1-naphthyl group, heptafluoro-1-naphthyl group, 1-fluoro-2-naphthyl group, 5-fluoro-2-naphthyl group, 6-fluoro-2-naphthyl group, 7-fluoro-2-naphthyl group, 5,7-difluoro-2-naphthyl group, and heptafluoro-2-naphthyl group.

The halogenated aralkyl group is an aralkyl group substituted with a halogen atom, and specific examples of the aralkyl group and the halogen atom are the same as those described above.

No particular limitation is imposed on the carbon atom number of the halogenated aralkyl group, but the carbon atom number is preferably 40 or less, more preferably 30 or less, still more preferably 20 or less.

Specific examples of the halogenated aralkyl group include, but are not limited to, 2-fluorobenzyl group, 3-fluorobenzyl group, 4-fluorobenzyl group, 2,3-difluorobenzyl group, 2,4-difluorobenzyl group, 2,5-difluorobenzyl group, 2,6-difluorobenzyl group, 3,4-difluorobenzyl group, 3,5-difluorobenzyl group, 2,3,4-trifluorobenzyl group, 2,3,5-trifluorobenzyl group, 2,3,6-trifluorobenzyl group, 2,4,5-trifluorobenzyl group, 2,4,6-trifluorobenzyl group, 2,3,4,5-tetrafluorobenzyl group, 2,3,4,6-tetrafluorobenzyl group, 2,3,5,6-tetrafluorobenzyl group, and 2,3,4,5,6-pentafluorobenzyl group.

The alkoxyalkyl group is an alkyl group substituted with an alkoxy group. Specific examples of the alkyl group are the same as those described above.

Examples of the alkoxy group include, but are not limited to, alkoxy groups having a linear, branched, or cyclic alkyl moiety having a carbon atom number of 1 to 20, such as methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group; and cyclic alkoxy groups, such as cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

No particular limitation is imposed on the carbon atom number of the alkoxyalkyl group, but the carbon atom number is preferably 40 or less, more preferably 30 or less, still more preferably 20 or less, much more preferably 10 or less.

Specific examples of the alkoxyalkyl group include, but are not limited to, lower alkyloxy lower alkyl groups, such as methoxymethyl group, ethoxymethyl group, 1-ethoxyethyl group, 2-ethoxyethyl group, and ethoxymethyl group.

The alkoxyaryl group is an aryl group substituted with an alkoxy group, and specific examples of the alkoxy group and the aryl group are the same as those described above.

No particular limitation is imposed on the carbon atom number of the alkoxyaryl group, but the carbon atom number is preferably 40 or less, more preferably 30 or less, still more preferably 20 or less.

Specific examples of the alkoxyaryl group include, but are not limited to, 2-methoxyphenyl group, 3-methoxyphenyl group, 4-methoxyphenyl group, 2-(1-ethoxy)phenyl group, 3-(1-ethoxy)phenyl group, 4-(1-ethoxy)phenyl group, 2-(2-ethoxy)phenyl group, 3-(2-ethoxy)phenyl group, 4-(2-ethoxy)phenyl group, 2-methoxynaphthalen-1-yl group, 3-methoxynaphthalen-1-yl group, 4-methoxynaphthalen-1-yl group, 5-methoxynaphthalen-1-yl group, 6-methoxynaphthalen-1-yl group, and 7-methoxynaphthalen-1-yl group.

The alkoxyaralkyl group is an aralkyl group substituted with an alkoxy group, and specific examples of the alkoxy group and the aralkyl group are the same as those described above.

No particular limitation is imposed on the carbon atom number of the alkoxyaralkyl group, but the carbon atom number is preferably 40 or less, more preferably 30 or less, still more preferably 20 or less.

Specific examples of the alkoxyaralkyl group include, but are not limited to, 3-(methoxyphenyl)benzyl group and 4-(methoxyphenyl)benzyl group.

Examples of the aforementioned alkenyl group include C₂₋₁₀ alkenyl groups, such as ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group. Other examples include crosslinked cyclic alkenyl groups, such as bicycloheptenyl group (norbornyl group).

Examples of the substituent of the aforementioned alkyl group, aryl group, aralkyl group, halogenated alkyl group, halogenated aryl group, halogenated aralkyl group, alkoxyalkyl group, alkoxyaryl group, alkoxyaralkyl group, and alkenyl group include alkyl group, aryl group, aralkyl group, halogenated alkyl group, halogenated aryl group, halogenated aralkyl group, alkoxyalkyl group, aryloxy group, alkoxyaryl group, alkoxyaralkyl group, alkenyl group, alkoxy group, and aralkyloxy group. Specific examples of these groups and preferred carbon atom number thereof are the same as those described above or below.

The aforementioned aryloxy group is an aryl group bonded via an oxygen atom (—O—). Specific examples of the aryl group are the same as those described above. No particular limitation is imposed on the carbon atom number of the aryloxy group, but the carbon atom number is preferably 40 or less, more preferably 30 or less, still more preferably 20 or less. Specific examples of the aryloxy group include, but are not limited to, phenoxy group and naphthalen-2-yloxy group.

When two or more substituents are present, the substituents may be bonded together to form a ring.

Examples of the organic group containing an epoxy group include, but are not limited to, glycidoxymethyl group, glycidoxyethyl group, glycidoxypropyl group, glycidoxybutyl group, and epoxycyclohexyl group.

Examples of the organic group containing an acryloyl group include, but are not limited to, acryloylmethyl group, acryloylethyl group, and acryloylpropyl group.

Examples of the organic group containing a methacryloyl group include, but are not limited to, methacryloylmethyl group, methacryloylethyl group, and methacryloylpropyl group.

Examples of the organic group containing a mercapto group include, but are not limited to, ethylmercapto group, butylmercapto group, hexylmercapto group, and octylmercapto group.

Examples of the organic group containing an amino group include, but are not limited to, amino group, aminomethyl group, aminoethyl group, dimethylaminoethyl group, and dimethylaminopropyl group.

Examples of the organic group containing an amino group or an amide group include cyanuric acid derivatives.

Examples of the organic group containing a sulfonyl group include, but are not limited to, sulfonylalkyl group and sulfonylaryl group.

In Formula (1), R³ is a group or atom bonded to a silicon atom, and is each independently a hydroxy group, an alkoxy group, an aralkyloxy group, an acyloxy group, or a halogen atom. Examples of the alkoxy group and the halogen atom are the same as those described above.

The aralkyloxy group is a group derived from an aralkyl alcohol through removal of a hydrogen atom from the hydroxy group of the alcohol. Specific examples of the aralkyl group are the same as those described above.

No particular limitation is imposed on the carbon atom number of the aralkyloxy group, but the carbon atom number is preferably 40 or less, more preferably 30 or less, still more preferably 20 or less.

Specific examples of the aralkyloxy group include, but are not limited to, phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl-n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a group derived from a carboxylic compound through removal of a hydrogen atom from the carboxylic group of the compound. Typical examples of the acyloxy group include, but are not limited to, an alkylcarbonyloxy group, an arylcarbonyloxy group, and an aralkylcarbonyloxy group, which are respectively derived from an alkylcarboxylic acid, an arylcarboxylic acid, and an aralkylcarboxylic acid through removal of a hydrogen atom from the carboxylic group of the acid. Specific examples of the alkyl group, the aryl group, and the aralkyl group of such alkylcarboxylic acid, arylcarboxylic acid, and aralkylcarboxylic acid are the same as those described above.

Specific examples of the acyloxy group include, but are not limited to, C₁₋₂₀ acyloxy groups, such as methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

In Formula (1), a is an integer of 1, b is an integer of 0 to 2, and a +b is an integer of 1 to 3.

In Formula (1), b is preferably 0 or 1, more preferably 0.

Specific examples of the silane having a cyano group in the molecule and being of Formula (1) include, but are not limited to, silanes of the following Formulae (1-1-1) to (1-8-1). In each Formula, T is each independently a hydroxy group or a C₁₋₃ alkoxy group. In particular, T is preferably an ethoxy group, a methoxy group, or a hydroxy group.

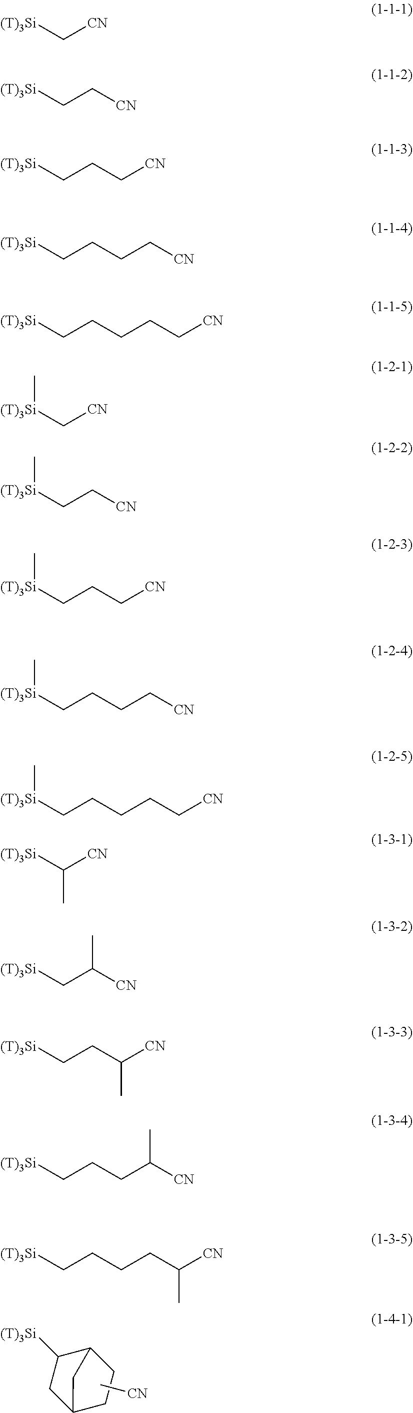

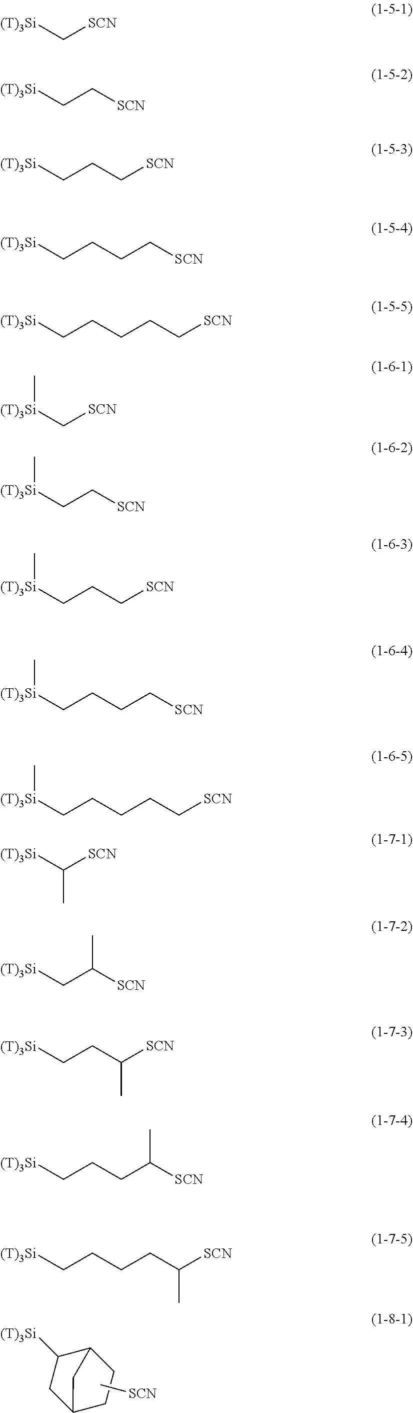

[Additional Hydrolyzable Silane]

In the present invention, the aforementioned hydrolyzable silane compound may contain at least one selected from among a hydrolyzable silane of the following Formula (2) and a hydrolyzable silane of the following Formula (3) (additional hydrolyzable silane) together with the hydrolyzable silane having a cyano group in the molecule and being of Formula (1) for the purpose of, for example, adjusting film properties such as film density. Of these additional hydrolyzable silanes, the hydrolyzable silane of Formula (2) is preferred.

R⁴_{c}Si(R⁵)_{4-c} (2)

In Formula (2), R⁴ is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these.

R⁵ is a group or atom bonded to a silicon atom, and is each independently an alkoxy group, an aralkyloxy group, an acyloxy group, or a halogen atom.

In Formula (2), c is an integer of 0 to 3.

Specific examples of each group of R⁴ and the preferred carbon atom number thereof are the same as those described above in R².

Specific examples of each group of R⁵ and the preferred carbon atom number thereof are the same as those described above in R³.

In Formula (2), c is preferably 0 or 1, more preferably 0.

[R⁶_{d}Si(R⁷)_{3-d}]₂Yₑ (3)

In Formula (3), R⁶ is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these.

R⁷ is a group or atom bonded to a silicon atom, and is each independently an alkoxy group, an aralkyloxy group, an acyloxy group, or a halogen atom.

Y is a group bonded to a silicon atom via an Si—C bond, and is each independently an alkylene group or an arylene group.

In Formula (3), d is an integer of 0 or 1, and e is an integer of 0 or 1.

Specific examples of each group of R⁶ and the preferred carbon atom number thereof are the same as those described above in R².

Specific examples of each group of R⁷ and the preferred carbon atom number thereof are the same as those described above in R³.

Specific examples of the alkylene group of Y include, but are not limited to, alkylene groups, for example, linear alkylene groups such as methylene group, ethylene group, trimethylene group, tetramethylene group, pentamethylene group, hexamethylene group, heptamethylene group, octamethylene group, nonamethylene group, and decamethylene group, and branched alkylene groups such as 1-methyltrimethylene group, 2-methyltrimethylene group, 1,1-dimethylethylene group, 1-methyltetramethylene group, 2-methyltetramethylene group, 1,1-dimethyltrimethylene group, 1,2-dimethyltrimethylene group, 2,2-dimethyltrimethylene group, and 1-ethyltrimethylene group; and alkanetriyl groups such as methanetriyl group, ethane-1,1,2-triyl group, ethane-1,2,2-triyl group, ethane-2,2,2-triyl group, propane-1,1,1-triyl group, propane-1,1,2-triyl group, propane-1,2,3-triyl group, propane-1,2,2-triyl group, propane-1,1,3-triyl group, butane-1,1,1-triyl group, butane-1,1,2-triyl group, butane-1,1,3-triyl group, butane-1,2,3-triyl group, butane-1,2,4-triyl group, butane-1,2,2-triyl group, butane-2,2,3-triyl group, 2-methylpropane-1,1,1-triyl group, 2-methylpropane-1,1,2-triyl group, 2-methylpropane-1,1,3-triyl group, and 2-methylpropane-1,1,1-triyl group.

Specific examples of the arylene group include, but are not limited to, 1,2-phenylene group, 1,3-phenylene group, 1,4-phenylene group; groups derived from a condensed-ring aromatic hydrocarbon compound through removal of two hydrogen atoms on the aromatic ring, such as 1,5-naphthalenediyl group, 1,8-naphthalenediyl group, 2,6-naphthalenediyl group, 2,7-naphthalenediyl group, 1,2-anthracenediyl group, 1,3-anthracenediyl group, 1,4-anthracenediyl group, 1,5-anthracenediyl group, 1,6-anthracenediyl group, 1,7-anthracenediyl group, 1,8-anthracenediyl group, 2,3-anthracenediyl group, 2,6-anthracenediyl group, 2,7-anthracenediyl group, 2,9-anthracenediyl group, 2,10-anthracenediyl group, and 9,10-anthracenediyl group; and groups derived from a linked-ring aromatic hydrocarbon compound through removal of two hydrogen atoms on the aromatic ring, such as 4,4′-biphenyldiyl group and 4,4″-p-terphenyldiyl group.

In Formula (3), d is preferably 0 or 1, more preferably 0.

Furthermore, e is preferably 1.

Specific examples of the hydrolyzable silane of Formula (2) include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltrimethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, a-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltiimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltrichlorosilane, vinyltriacetoxysilane, vinyltriethoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, chloromethyltrimethoxysilane, chloromethyltriethoxysilane, triethoxysilylpropyldiallyl isocyanurate, bicyclo(2,2,1)heptenyltriethoxysilane, benzenesulfonylpropyltriethoxysilane, benzenesulfonamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, and silanes of the following Formulae (A-1) to (A-41).

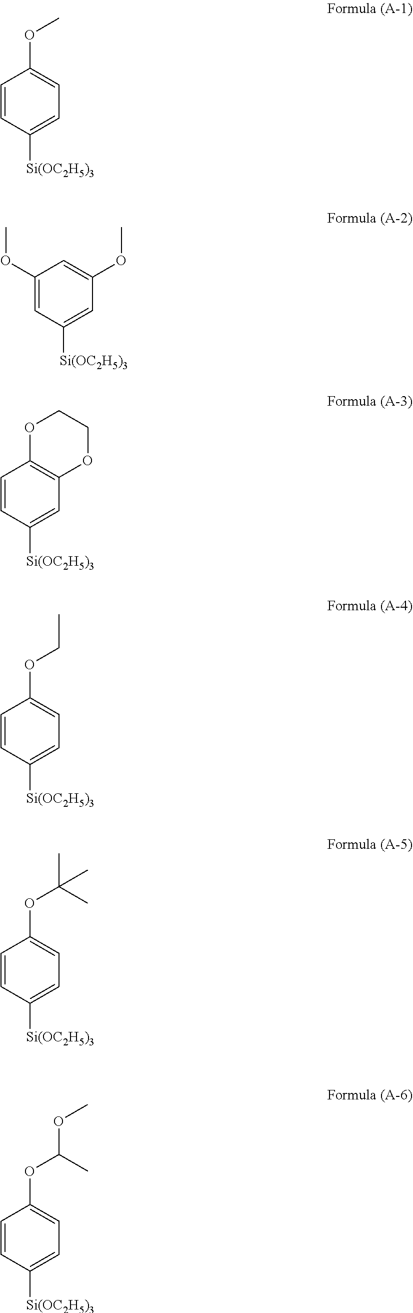

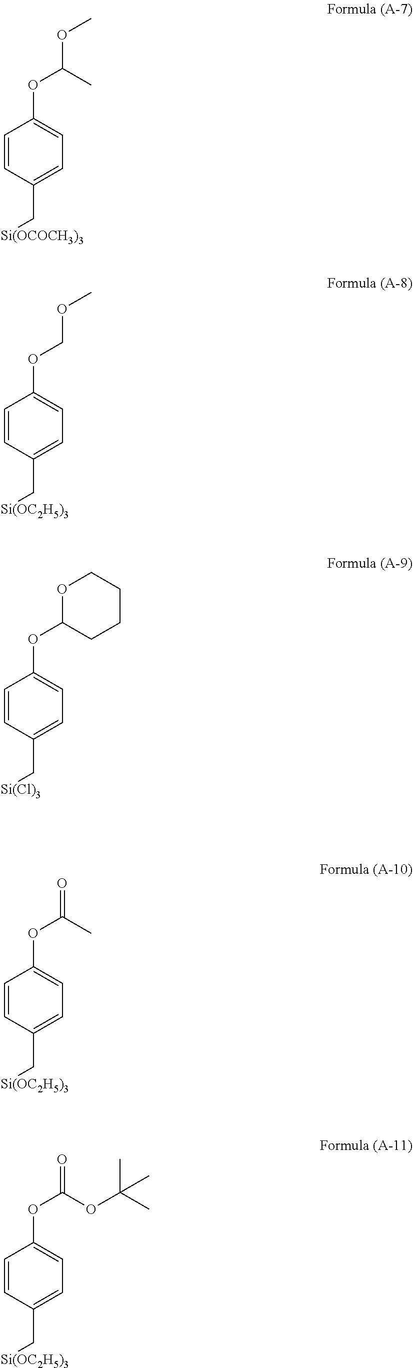

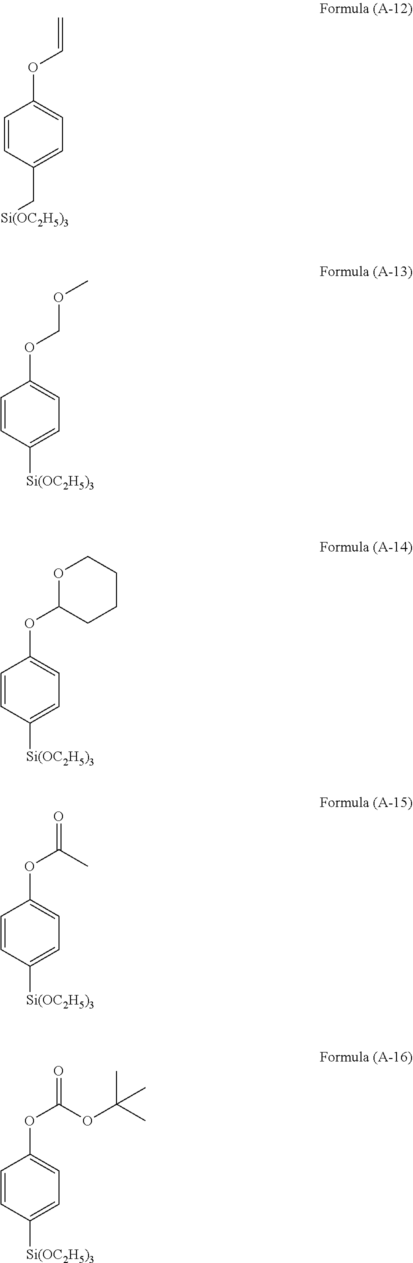

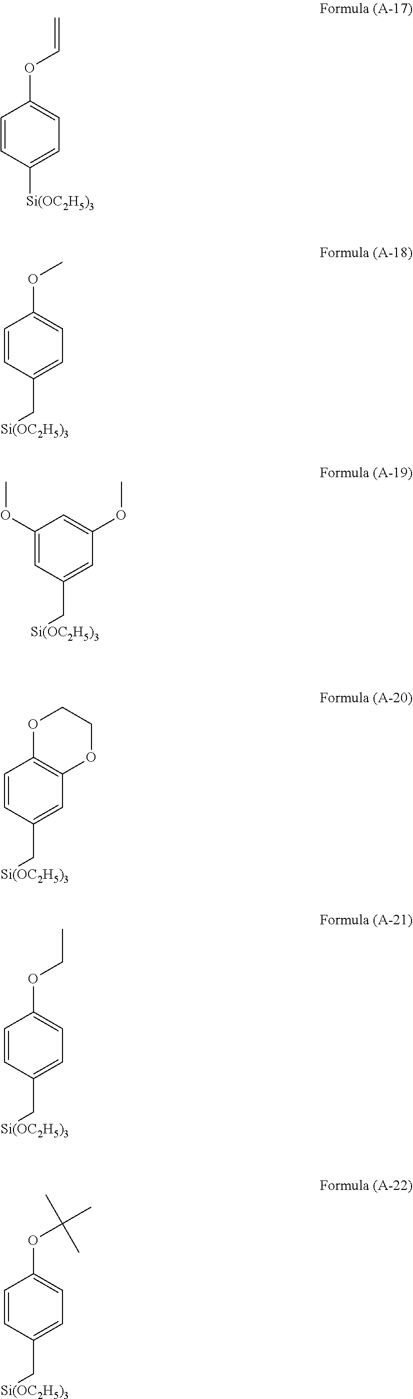

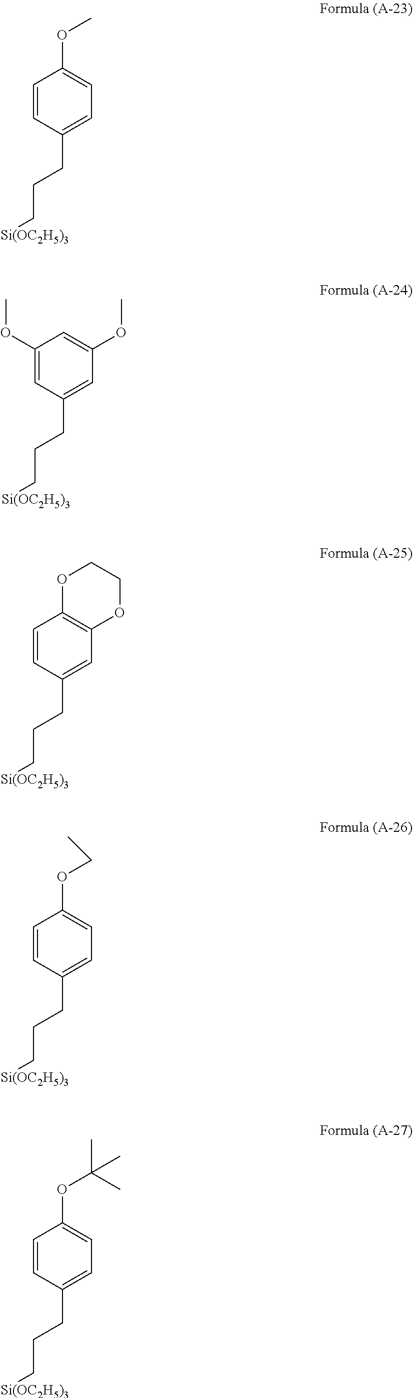

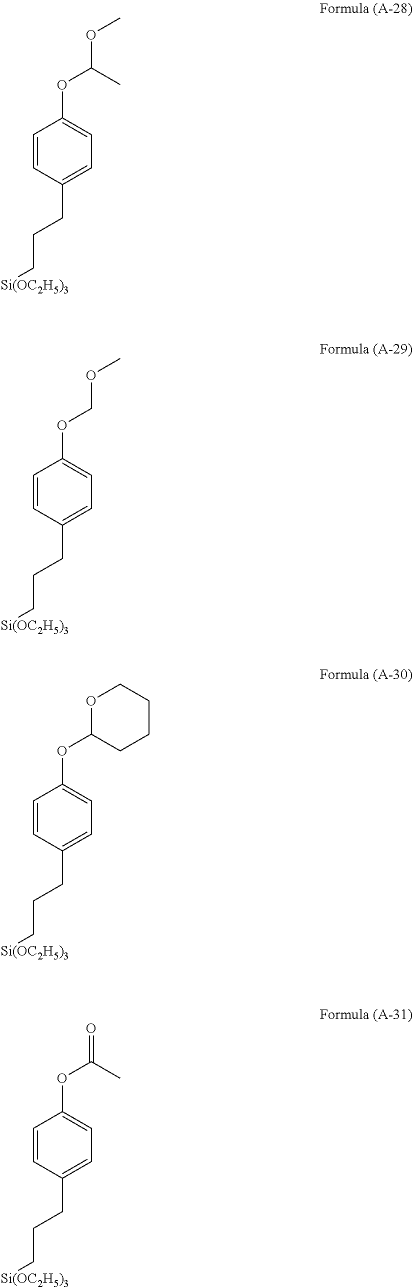

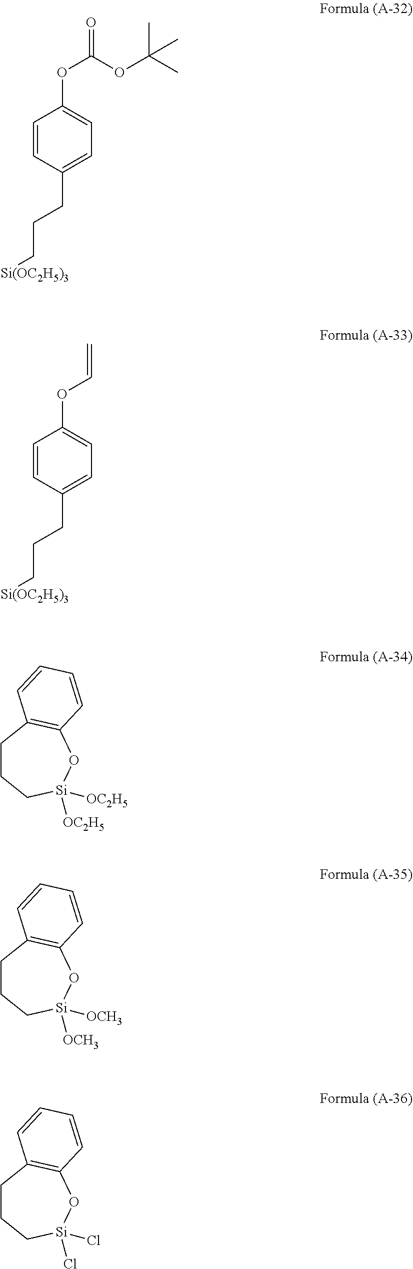

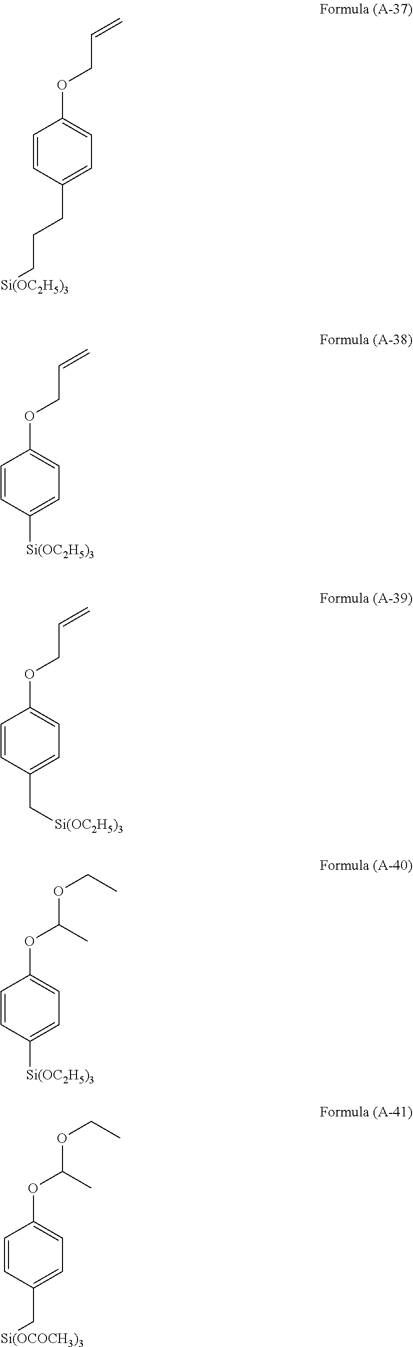

Of these, a tetrafunctional silane such as tetramethoxysilane or tetraethoxysilane is preferably used as an essential component, from the viewpoints of, for example, increasing the crosslinked density of a film formed from the composition of the present invention, reducing diffusion, etc. of a component of a resist film into the film formed from the composition, and maintaining and improving the resist properties of the resist film.

Specific examples of the hydrolyzable silane of Formula (3) induce, but are not limited to, methylencbistrimethoxysilane, methylenebistrichlorosilane, methylenebistriacetoxysilane, ethylenebistriethoxysilane, ethylenebistrichlorosilane, ethylenebistriacetoxysilane, propylenebisidethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxydisilane, bistriethoxydisilane, bisethyldiethoxydisilane, and bismethyldimethoxydisilane.

In the present invention, the aforementioned hydrolyzable silane compound may contain a hydrolyzable organosilane having an onium group in the molecule. The use of a hydrolyzable organosilane having an onium group in the molecule can effectively and efficiently promote the crosslinking reaction of the hydrolyzable silane.

A preferred example of such a hydrolyzable organosilane having an onium group in the molecule is shown in the following Formula (4).

R³¹_{f}R³²_{g}Si(R³³)_{4-(f+g)} (4)

R³¹ is a group bonded to a silicon atom, and is an onium group or an organic group containing the onium group.

R³² is a group bonded to a silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, or an amino group, or any combination of these.

R³³ is a group or atom bonded to a silicon atom, and is each independently an alkoxy group, an aralkyloxy group, an acyloxy group, or a halogen atom.

In Formula (4), f is 1 or 2, g is 0 or 1, and f and g satisfy a relation of 1≤f+g≤2.

Specific examples of the aforementioned alkyl group, aryl group, aralkyl group, halogenated alkyl group, halogenated aryl group, halogenated aralkyl group, alkoxyalkyl group, alkoxyaryl group, alkoxyaralkyl group, alkenyl group, organic group containing an epoxy group, an acryloyl group, a methacryloyl group, a mercapto group, or an amino group, alkoxy group, aralkyloxy group, acyloxy group, or halogen atom, and the substituent of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group and preferred carbon atom numbers thereof are the same as those described above. Specifically, examples of each group of R³² and the preferred carbon atom number thereof are the same as those described above in R², and examples of each group of R³³ and the preferred carbon atom number thereof are the same as those described above in R³.

More specifically, the onium group is, for example, a cyclic ammonium group or a chain ammonium group, and is preferably a tertiary ammonium group or a quaternary ammonium group.

As preferred specific examples of the onium group or the organic group containing the onium group, a cyclic ammonium group or a chain ammonium group, or an organic group containing at least one of these ammonium groups may be exemplified. Preferred is a tertiary ammonium group or a quaternary ammonium group, or an organic group containing at least one of these ammonium groups.

When the onium group is a cyclic ammonium group, a nitrogen atom forming the ammonium group also serves as an atom forming the ring. In this case, the nitrogen atom forming the ring and a silicon atom are bonded directly or via a divalent linking group, or the carbon atom forming the ring and the silicon atom are bonded directly or via a divalent linking group.

In one preferred embodiment of the present invention, R³¹ (i.e., the group bonded to a silicon atom) is a heteroaromatic cyclic ammonium group of the following Formula (S1).

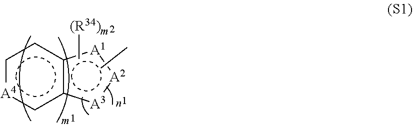

In Formula (S1), A¹, A², A³, and A⁴ are each independently a group of any of the following Formulae (J1) to (J3), and at least one of A¹ to A⁴ is a group of the following Formula (J2). Depending on the bonding between a silicon atom in Formula (4) and any of A¹ to A⁴, each of A¹ to A⁴ and the ring-forming atom adjacent thereto forms a single bond or a double bond. This determines whether the thus-formed ring exhibits aromaticity.

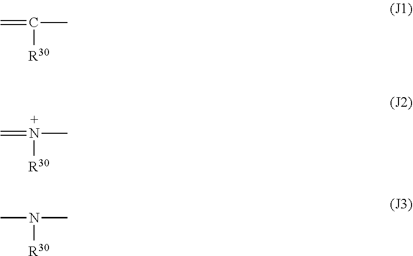

In Formulae (J1) to (J3), R³⁰ is each independently a single bond, a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S1), R³⁴ is each independently an alkyl group, an aryl group, an aralkyl group, a halogenated alkyl group, a halogenated aryl group, a halogenated aralkyl group, an alkenyl group, or a hydroxy group. When two or more R³⁴s are present, the two R³⁴s may be bonded together to form a ring, and the ring formed by the two R³⁴s may have a crosslinked ring structure. In such a case, the cyclic ammonium group has, for example, an adamantane ring, a norbornene ring, or a spiro ring.

Specific examples of these alkyl group, aryl group, aralkyl group, halogenated alkyl group, halogenated aryl group, halogenated aralkyl group, and alkenyl group, and preferred carbon atom numbers thereof are the same as those described above.

In Formula (S1), n¹ is an integer of 1 to 8; m¹ is 0 or 1; and m² is 0 or a positive integer ranging from 1 to the possible maximum number of R³⁴s substituted on a monocyclic or polycyclic ring.

When m¹ is 0, a (4+n¹)-membered ring including A¹ to A⁴ is formed. Specifically, when n¹ is 1, a 5-membered ring is formed; when n¹ is 2, a 6-membered ring is formed; when n¹ is 3, a 7-membered ring is formed; when n¹ is 4, an 8-membered ring is formed; when n¹ is 5, a 9-membered ring is formed; when n¹ is 6, a 10-membered ring is formed; when n¹ is 7, an 11-membered ring is formed; and when n¹ is 8, a 12-membered ring is formed.

When m¹ is 1, a condensed ring is formed by condensation between a (4+n¹)-membered ring including A¹ to A³ and a 6-membered ring including A⁴.

Since each of A¹ to A⁴ is any of the groups of Formulae (J1) to (J3), the ring-forming atom has or does not have a hydrogen atom. In each of A¹ to A⁴, when the ring-forming atom has a hydrogen atom, the hydrogen atom may be substituted with R³⁴. Alternatively, a ring-forming atom other than the ring-forming atom in each of A¹ to A⁴ may be substituted with R³⁴. Because of these circumstances, m² is 0 or an integer ranging from 1 to the possible maximum number of R³⁴s substituted on a monocyclic or polycyclic ring.

The bonding hand of the heteroaromatic cyclic ammonium group of Formula (S1) is present on any carbon atom or nitrogen atom present in such a monocyclic or polycyclic ring, and is directly bonded to a silicon atom. Alternatively, the bonding hand is bonded to a linking group to form an organic group containing the cyclic ammonium, and the organic group is bonded to a silicon atom.

Examples of the linking group include, but are not limited to, an alkylene group, an arylene group, and an alkenylene group.

Specific examples of the alkylene group and the arylene group, and preferred carbon atom numbers thereof are the same as those described above.

The alkenylene group is a divalent group derived from an alkenyl group through removal of one hydrogen atom. Specific examples of the alkenyl group are the same as those described above. No particular limitation is imposed on the carbon atom number of the alkenylene group, but the carbon atom number is preferably 40 or less, more preferably 30 or less, still more preferably 20 or less.

Specific examples of the alkenylene group include, but are not limited to, vinylene group, 1-methylvinylene group, propenylene group, 1-butenylene group, 2-butenylene group, 1-pentenylene group, and 2-pentenylene group.

Specific examples of the hydrolyzable organosilane of Formula (4) having the heteroaromatic cyclic ammonium group of Formula (S1) include, but are not limited to, silanes of the following Formulae (I-1) to (I-80).

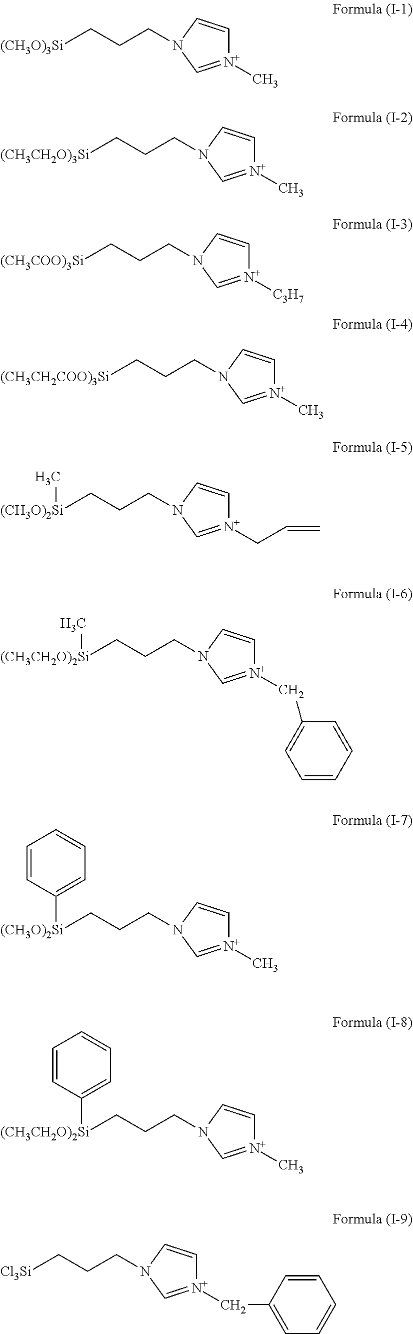

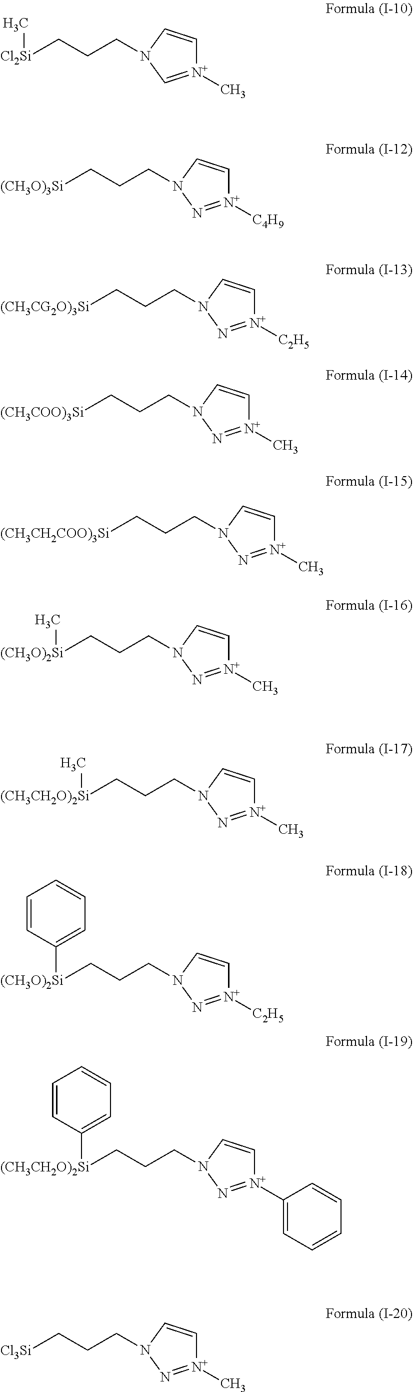

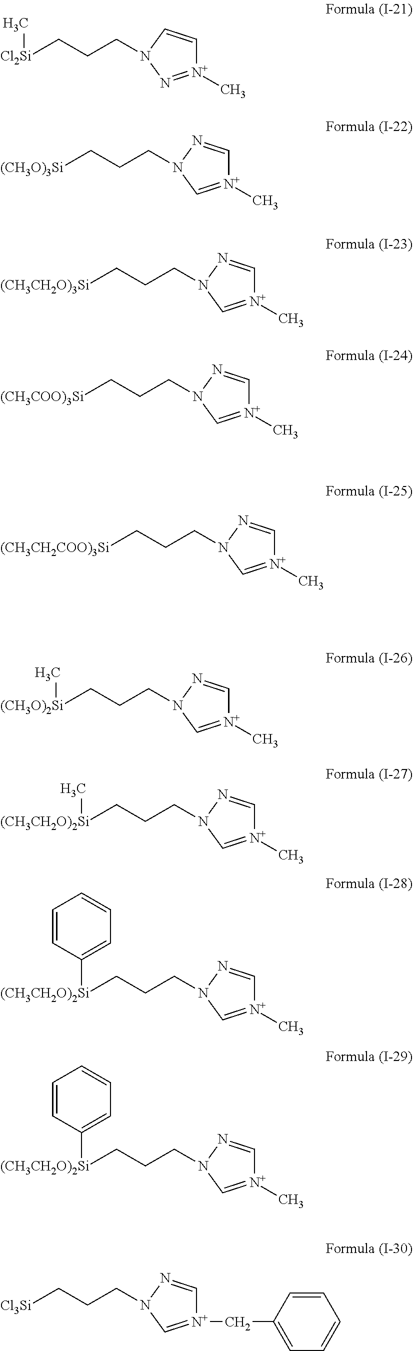

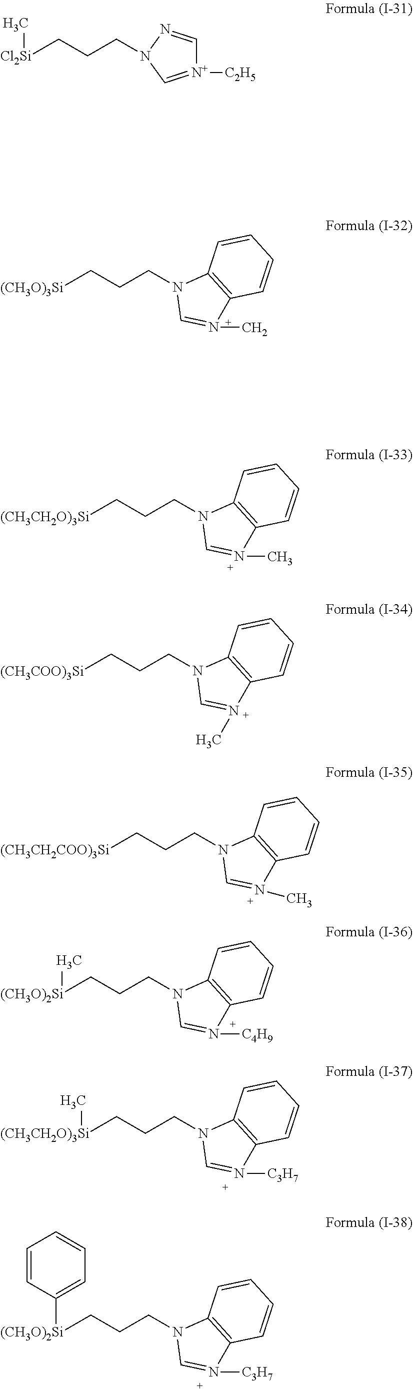

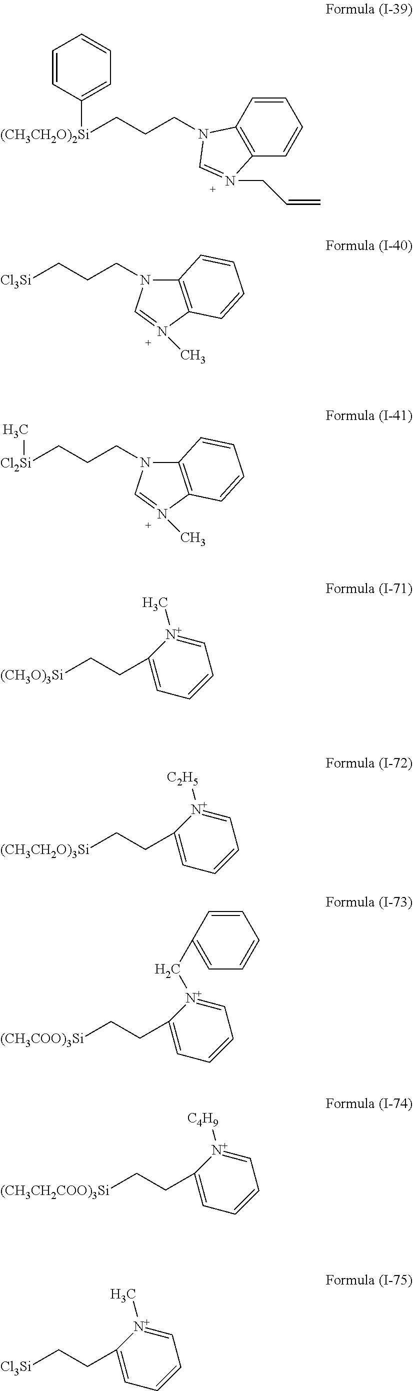

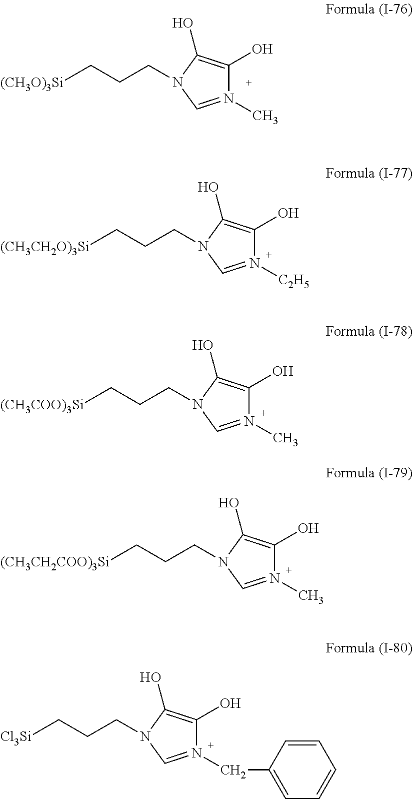

In another embodiment, R³¹, which is a group bonded to a silicon atom in Formula (4), may be a heteroaliphatic cyclic ammonium group of the following Formula (S2).

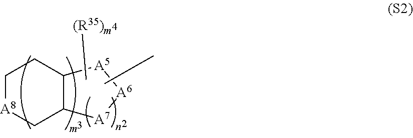

In Formula (S2), A⁵, A⁶, A⁷, and A⁸ are each independently a group of any of the following Formulae (J4) to (J6), and at least one of A⁵ to A⁸ is a group of the following Formula (J5). Depending on the bonding between a silicon atom in Formula (4) and any of A⁵ to A⁸, each of A⁵ to A⁸ and the ring-forming atom adjacent thereto forms a single bond or a double bond. This determines whether the thus-formed ring exhibits anti-aromaticity.

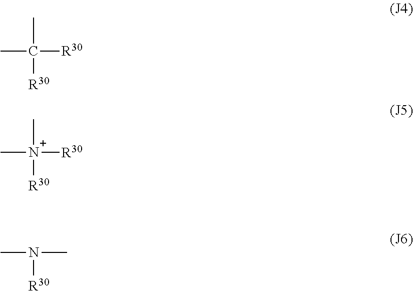

In Formulae (J4) to (J6), R³⁰ is each independently a single bond, a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S2), R³⁵ is each independently an alkyl group, an aryl group, an aralkyl group, a halogenated alkyl group, a halogenated aryl group, a halogenated aralkyl group, an alkenyl group, or a hydroxy group. When two or more R³⁵s are present, the two R³⁵s may be bonded together to form a ring, and the ring formed by the two R³⁵s may have a crosslinked ring structure. In such a case, the cyclic ammonium group has, for example, an adamantane ring, a norbornene ring, or a spiro ring.

Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S2), n² is an integer of 1 to 8; m³ is 0 or 1; and m⁴ is 0 or a positive integer ranging from 1 to the possible maximum number of R³⁵s substituted on a monocyclic or polycyclic ring.

When m³ is 0, a (4+n²)-membered ring including A⁵ to A⁸ is formed. Specifically, when n² is 1, a 5-membered ring is formed; when n² is 2, a 6-membered ring is formed; when n² is 3, a 7-membered ring is formed; when n² is 4, an 8-membered ring is formed; when n² is 5, a 9-membered ring is formed; when n² is 6, a 10-membered ring is formed; when n² is 7, an 11-membered ring is formed; and when n² is 8, a 12-membered ring is formed.

When m³ is 1, a condensed ring is formed by condensation between a (4+n²)-membered ring including A⁵ to A⁷ and a 6-membered ring including A⁸.

Since each of A⁵ to A⁸ is any of the groups of Formulae (J4) to (J6), the ring-forming atom has or does not have a hydrogen atom. In each of A⁵ to A⁸, when the ring-forming atom has a hydrogen atom, the hydrogen atom may be substituted with R³⁵. Alternatively, a ring-forming atom other than the ring-forming atom in each of A⁵ to A⁸ may be substituted with R³⁵.

Because of these circumstances, m⁴ is 0 or an integer ranging from 1 to the possible maximum number of R³⁵s substituted on a monocyclic or polycyclic ring.

The bonding hand of the heteroaliphatic cyclic ammonium group of Formula (S2) is present on any carbon atom or nitrogen atom present in such a monocyclic or polycyclic ring, and is directly bonded to a silicon atom. Alternatively, the bonding hand is bonded to a linking group to form an organic group containing the cyclic ammonium, and the organic group is bonded to a silicon atom.

The linking group is, for example, an alkylene group, an arylene group, or an alkenylene group. Specific examples of the alkylene group, the arylene group, and the alkenylene group, and preferred carbon atom numbers thereof are the same as those described above.

Specific examples of the hydrolyzable organosilane of Formula (4) having the heteroaliphatic cyclic ammonium group of Formula (S2) include, but are not limited to, silanes of the following Formulae (II-1) to (II-31).

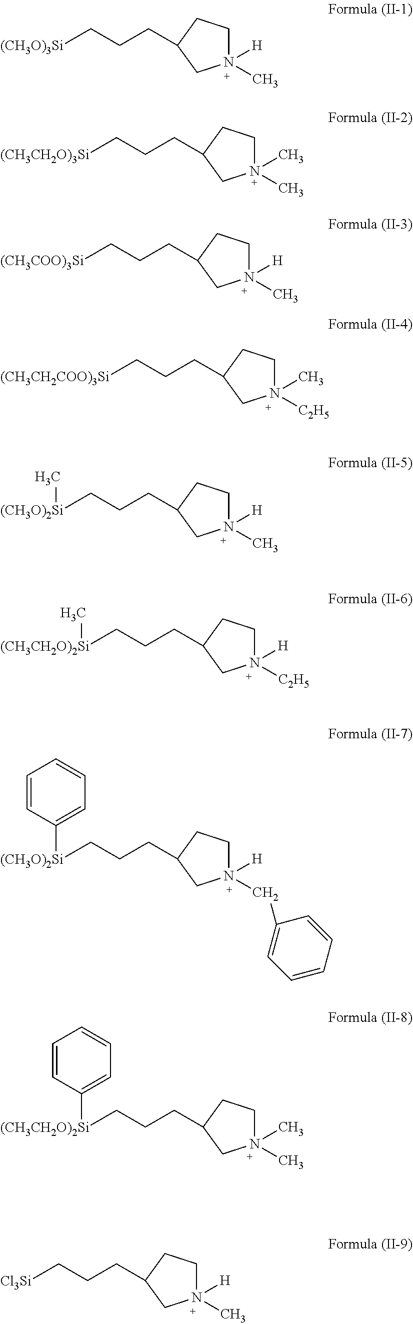

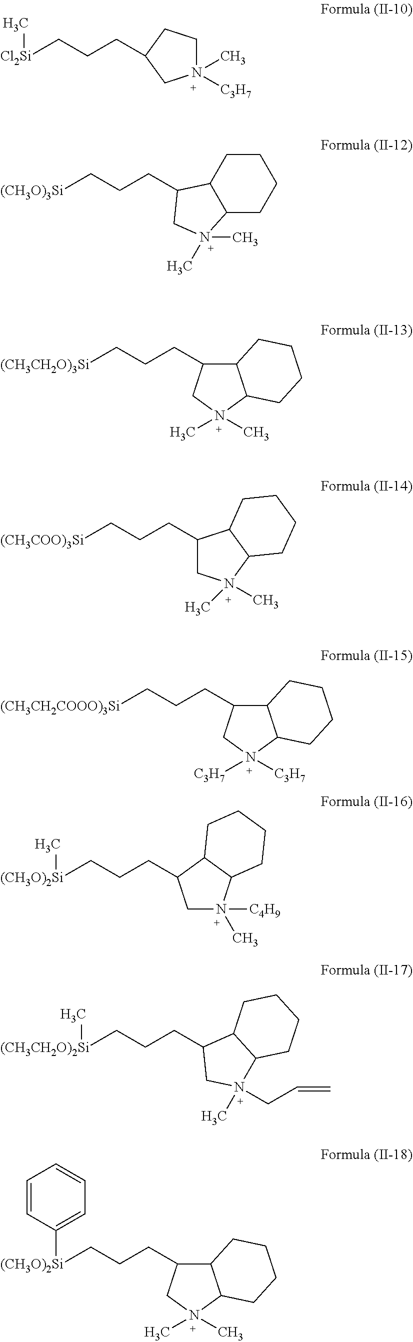

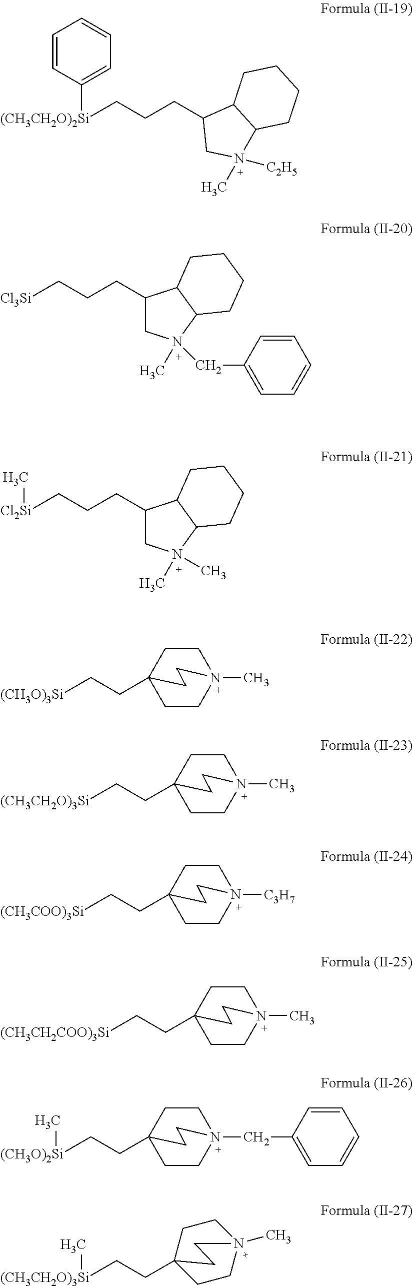

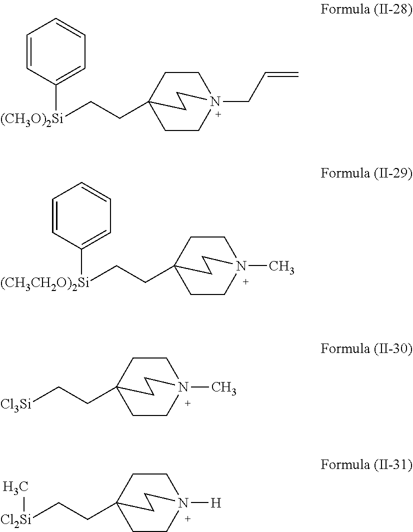

In yet another embodiment, R³¹, which is a group bonded to a silicon atom in Formula (4), may be a chain ammonium group of the following Formula (S3).

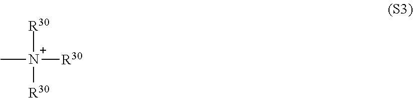

In Formula (S3), R³⁰ is each independently a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

The chain ammonium group of Formula (S3) is directly bonded to a silicon atom. Alternatively, the chain ammonium group is bonded to a linking group to form an organic group containing the chain ammonium group, and the organic group is bonded to a silicon atom.

The linking group is, for example, an alkylene group, an arylene group, or an alkenylene group. Specific examples of the alkylene group, the arylene group, and the alkenylene group are the same as those described above.

Specific examples of the hydrolyzable organosilane of Formula (4) having the chain ammonium group of Formula (S3) include, but are not limited to, silanes of the following Formulae (III-1) to (III-28).

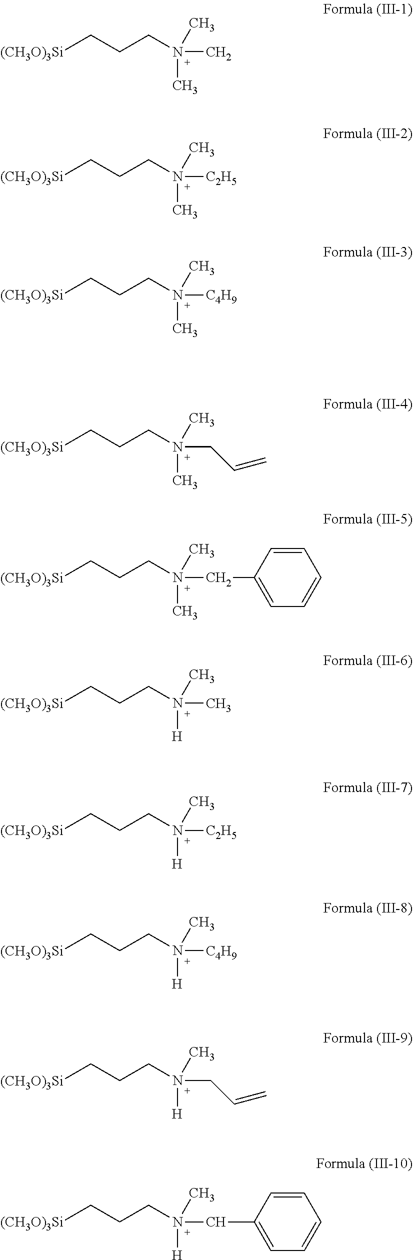

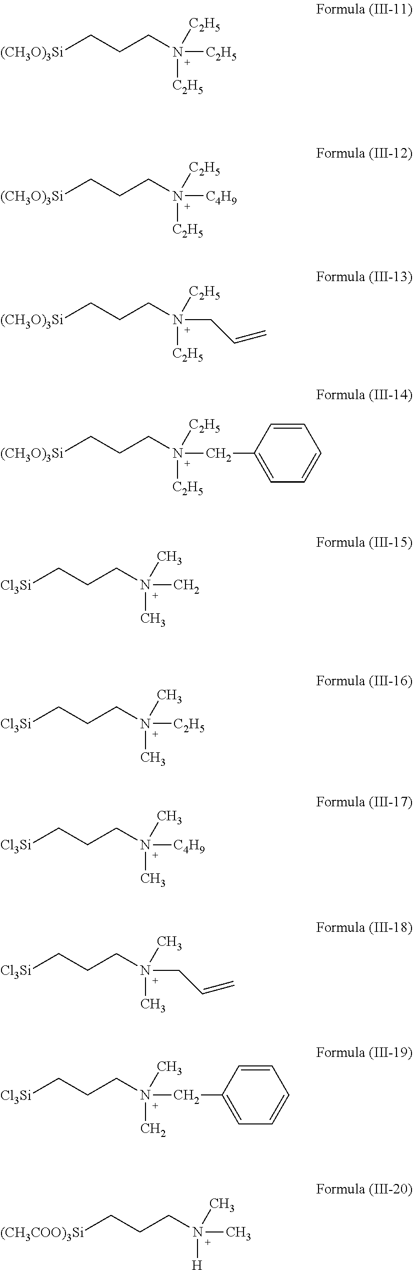

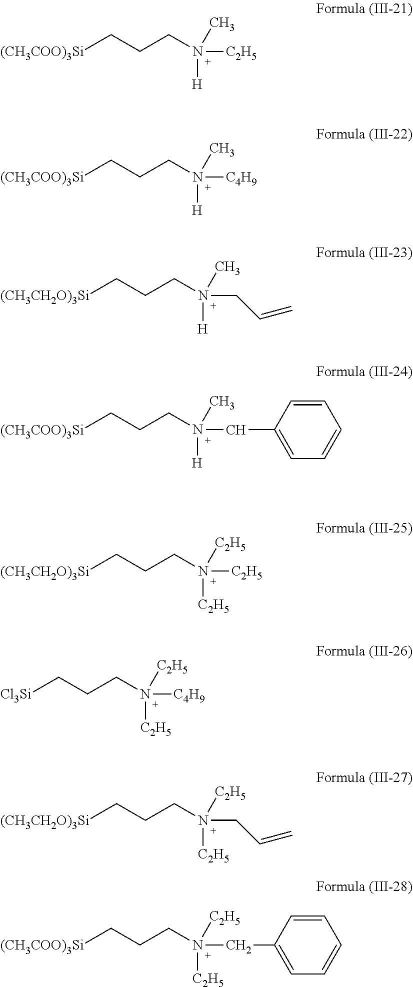

The film-forming composition of the present invention may further contain, as a hydrolyzable silane compound, a silane having a sulfone group or a silane having a sulfonamide group. Specific examples of such a silane include, but are not limited to, silanes of the following Formulae (B-1) to (B-36).

In the following Formulae, Me is a methyl group, and Et is an ethyl group.

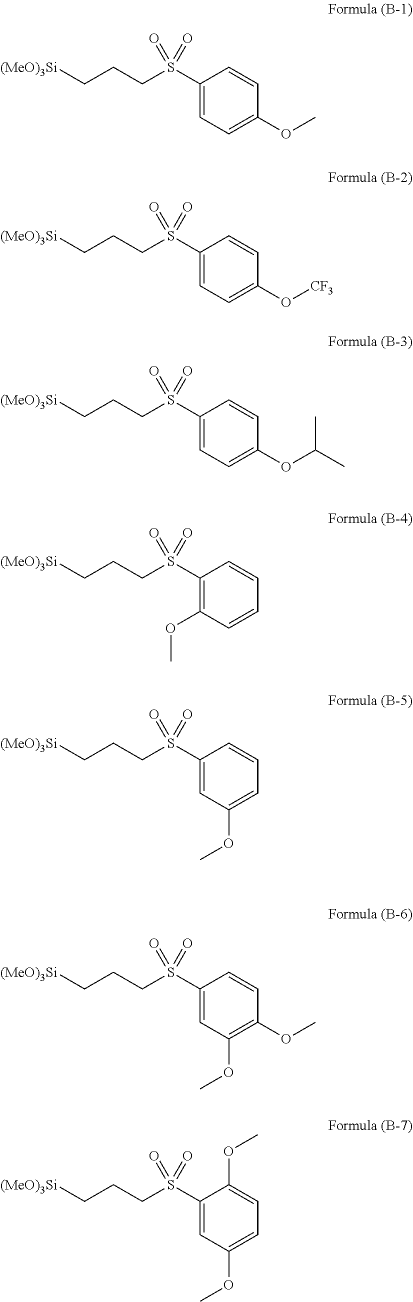

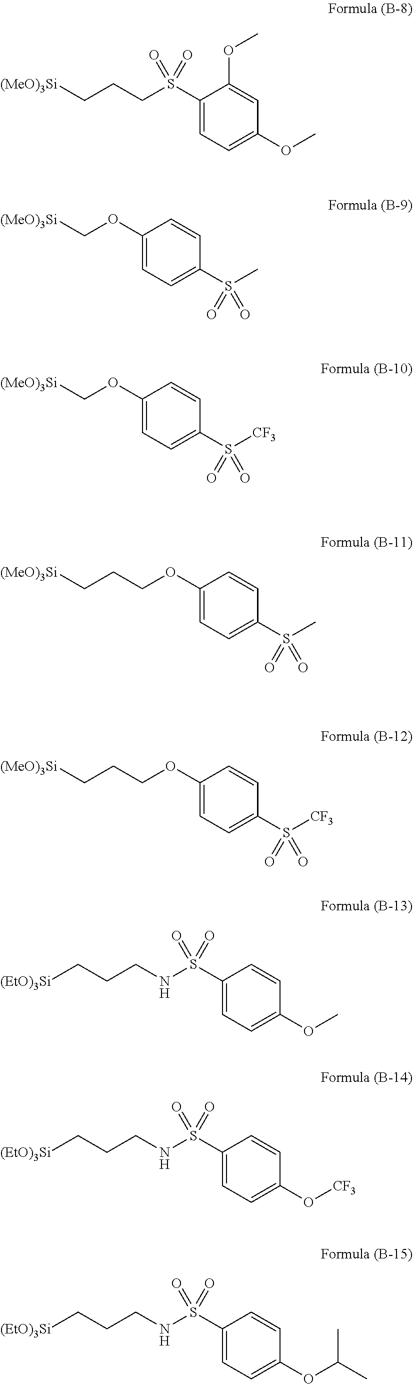

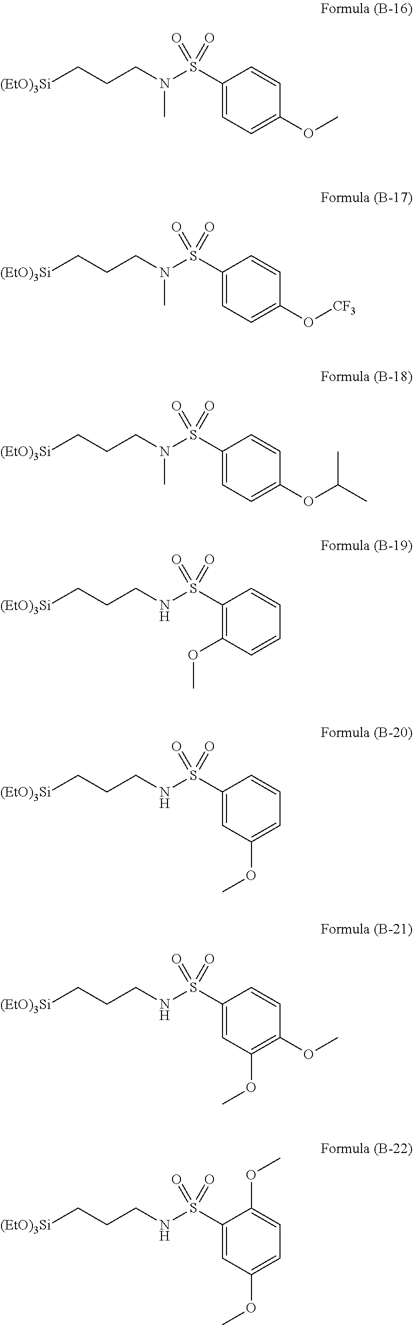

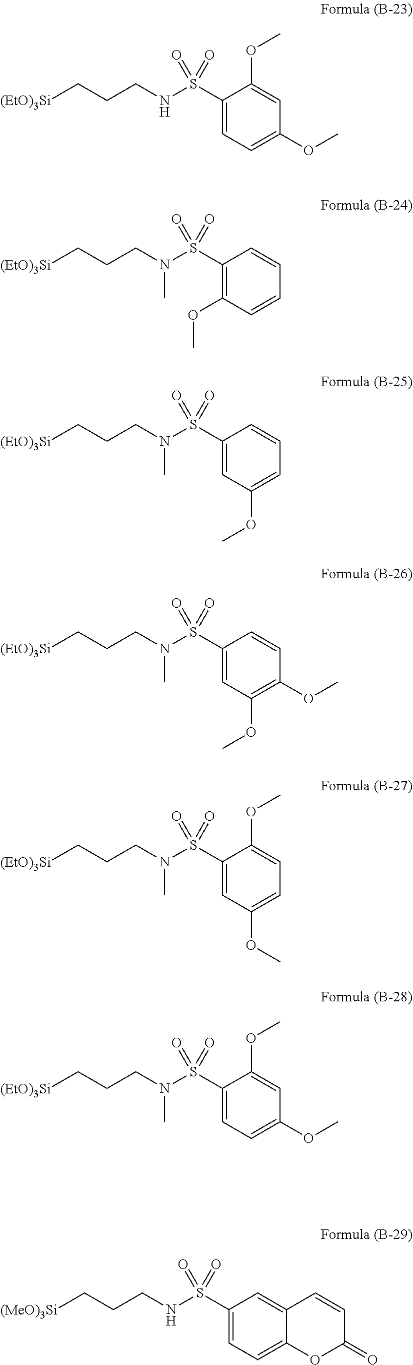

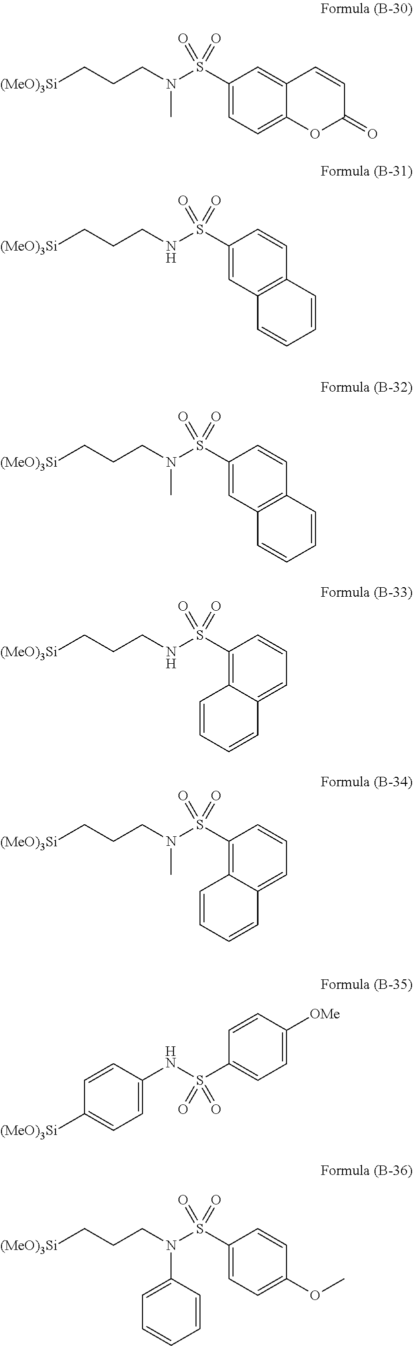

The hydrolyzable silane compound may contain a hydrolyzable silane other than the above-exemplified hydrolyzable silanes, so long as the effects of the present invention are not impaired.

In one preferred embodiment of the present invention, the film-forming composition of the present invention contains at least a hydrolysis condensate of the aforementioned hydrolyzable silane compound.

In one preferred embodiment of the present invention, the hydrolysis condensate contained in the film-forming composition of the present invention contains a hydrolysis condensate (polysiloxane) prepared from at least the hydrolyzable silane having a cyano group in the molecule and being of Formula (1), the hydrolyzable silane of Formula (2), and an optionally used additional hydrolyzable silane.

For example, the aforementioned hydrolysis condensate may be a hydrolysis condensate of the hydrolyzable silane compound containing a hydrolyzable silane having a cyano group in the molecule and being of Formula (1) in an amount of 0.1% by mole to 10% by mole relative to the entire amount of the hydrolyzable silane compound.

When a silane other than the hydrolyzable silane having a cyano group in the molecule and being of Formula (1) is used as a hydrolyzable silane compound, the amount of the hydrolyzable silane having a cyano group in the molecule and being of Formula (1) added may be, for example, 0.1% by mole to 50% by mole relative to the entire amount of the hydrolyzable silane compound. However, in a certain embodiment, the amount of the hydrolyzable silane may be, for example, 45% by mole or less, 40% by mole or less, 35% by mole or less, or 30% by mole or less, relative to the entire amount of the hydrolyzable silane compound. From the viewpoint of achieving the aforementioned effects of the present invention with high reproducibility, the amount of the hydrolyzable silane is preferably 0.5% by mole or more, more preferably 1% by mole or more, still more preferably 5% by mole or more, relative to the entire amount of the hydrolyzable silane compound.

When a hydrolyzable silane of Formula (2) or a hydrolyzable silane of Formula (3) is used as a hydrolyzable silane compound, the amount of the hydrolyzable silane added is generally 0.1% by mole or more, preferably 1% by mole or more, more preferably 5% by mole or more, and generally 99.9% by mole or less, preferably 99% by mole or less, more preferably 95% by mole or less, relative to the entire amount of the hydrolyzable silane compound.

When a hydrolyzable organosilane having an onium group in the molecule and being of Formula (4) is used as a hydrolyzable silane compound, the amount of the organosilane added is generally 0.01% by mole or more, preferably 0.1% by mole or more, and generally 30% by mole or less, preferably 10% by mole or less, relative to the entire amount of the hydrolyzable silane compound.

The aforementioned hydrolysis condensate of the hydrolyzable silane compound (may be referred to as “polysiloxane”) may have a weight average molecular weight of, for example, 500 to 1,000,000. From the viewpoint of, for example, preventing the precipitation of the hydrolysis condensate in the composition, the weight average molecular weight is preferably 500,000 or less, more preferably 250,000 or less, still more preferably 100,000 or less. From the viewpoint of, for example, the compatibility between storage stability and applicability, the weight average molecular weight is preferably 700 or more, more preferably 1,000 or more.

The weight average molecular weight is determined by GPC analysis in terms of polystyrene. The GPC analysis can be performed under, for example, the following conditions: GPC apparatus (trade name: HLC-8220GPC, available from Tosoh Corporation), GPC columns (trade name: Shodex KF803L, KF802, and KF801, available from Showa Denko K. K.), a column temperature of 40° C., tetrahydrofuran serving as an eluent (elution solvent), a flow amount (flow rate) of 1.0 mL/min, and polystyrene (available from Showa Denko K. K.) as a standard sample.

The hydrolysate or hydrolysis condensate of the aforementioned hydrolyzable silane compound can be prepared through hydrolysis of the hydrolyzable silane compound.

The hydrolyzable silane compound used in the present invention contains an alkoxy group, aralkyloxy group, acyloxy group, or halogen atom directly bonded to a silicon atom; specifically, a hydrolyzable group (i.e., an alkoxysilyl group, an aralkyloxysilyl group, an acyloxysilyl group, or a halogenated silyl group).

For the hydrolysis of the hydrolyzable group, generally 0.5 to 100 mol (preferably 1 mol to 10 mol) of water is used per mol of the hydrolyzable group.

During the hydrolysis, a hydrolysis catalyst may be used for the purpose of, for example, promoting the hydrolysis. Alternatively, the hydrolysis may be performed without use of a hydrolysis catalyst. When a hydrolysis catalyst is used, the amount of the hydrolysis catalyst is generally 0.0001 mol to 10 mol, preferably 0.001 mol to 1 mol, relative to 1 mol of the hydrolyzable group.

The reaction temperature of hydrolysis and condensation generally ranges from room temperature to the reflux temperature (at ambient pressure) of an organic solvent usable for the hydrolysis. The reaction temperature may be, for example, 20° C. to 110° C. or, for example, 20° C. to 80° C.

The hydrolysis may be completely performed (i.e., all hydrolyzable groups may be converted into silanol groups), or partially performed (i.e., unreacted hydrolyzable groups may remain). Thus, after the hydrolysis and the condensation reaction, the hydrolysis condensate may contain an uncondensed hydrolysate (complete hydrolysate or partial hydrolysate) or a monomer (hydrolyzable silane compound).

Examples of the hydrolysis catalyst usable for the hydrolysis and the condensation include a metal chelate compound, an organic acid, an inorganic acid, an organic base, and an inorganic base.

Examples of the metal chelate compound serving as a hydrolysis catalyst include, but are not limited to, titanium chelate compounds, such as triethoxy-mono(acetylacetonato)titanium, tri-n-propoxy-mono(acetylacetonato)titanium, tri-i-propoxy-mono(acetylacetonato)titanium, tri-n-butoxy-mono(acetylacetonato)titanium, tri-sec-butoxy-mono(acetylacetonato)titanium, tri-t-butoxy-mono(acetylacetonato)titanium, diethoxy-bis(acetylacetonato)titanium, di-n-propoxy-bis(acetylacetonato)titanium, di-i-propoxy-bis(acetylacetonato)titanium, di-n-butoxy-bis(acetylacetonato)titanium, di-sec-butoxy-bis(acetylacetonato)titanium, di-t-butoxy-bis(acetylacetonato)titanium, monoethoxy-tris(acetylacetonato)titanium, mono-n-propoxy-tris(acetylacetonato)titanium, mono-i-propoxy-tris(acetylacetonato)titanium, mono-n-butoxy-tris(acetylacetonato)titanium, mono-sec-butoxy-tris(acetylacetonato)titanium, mono-t-butoxy-tris(acetylacetonato)titanium, tetrakis(acetylacetonato)titanium, triethoxy-mono(ethylacetoacetato)titanium, tri-n-propoxy-mono(ethylacetoacetato)titanium, tri-i-propoxy-mono(ethylacetoacetato)titanium, tri-n-butoxy-mono(ethylacetoacetato)titanium, tri-sec-butoxy-mono(ethylacetoacetato)titanium, tri-t-butoxy-mono(ethylacetoacetato)titanium, diethoxy-bis(ethylacetoacetato)titanium, di-n-propoxy-bis(ethylacetoacetato)titanium, di-i-propoxy-bis(ethylacetoacetato)titanium, di-n-butoxy-bis(ethylacetoacetato)titanium, di-sec-butoxy-bis(ethylacetoacetato)titanium, di-t-butoxy-bis(ethylacetoacetato)titanium, monoethoxy-tris(ethylacetoacetato)titanium, mono-n-propoxy-tris(ethylacetoacetato)titanium, mono-i-propoxy-tris(ethylacetoacetato)titanium, mono-n-butoxy-tris(ethylacetoacetato)titanium, mono-sec-butoxy-tris(ethylacetoacetato)titanium, mono-t-butoxy-tris(ethylacetoacetato)titanium, tetrakis(ethylacetoacetato)titanium, mono(acetylacetonato)tris(ethylacetoacetato)titanium, bis(acetylacetonato)bis(ethylacetoacetato)titanium, and tris(acetylacetonato)mono(ethylacetoacetato)titanium; zirconium chelate compounds, such as triethoxy-mono(acetylacetonato)zirconium, tri-n-propoxy-mono(acetylacetonato)zirconium, tri-i-propoxy-mono(acetylacetonato)zirconium, tri-n-butoxy-mono(acetylacetonato)zirconium, tri-sec-butoxy-mono(acetylacetonato)zirconium, tri-t-butoxy-mono(acetylacetonato)zirconium, diethoxy-bis(acetylacetonato)zirconium, di-n-propoxy-bis(acetylacetonato)zirconium, di-i-propoxy-bis(acetylacetonato)zirconium, di-n-butoxy-bis(acetylacetonato)zirconium, di-sec-butoxy-bis(acetylacetonato)zirconium, di-t-butoxy-bis(acetylacetonato)zirconium, monoethoxy-tris(acetylacetonato)zirconium, mono-n-propoxy-tris(acetylacetonato)zirconium, mono-i-propoxy-tris(acetylacetonato)zirconium, mono-n-butoxy-tris(acetylacetonato)zirconium, mono-sec-butoxy-tris(acetylacetonato)zirconium, mono-t-butoxy-tris(acetylacetonato)zirconium, tetrakis(acetylacetonato)zirconium, triethoxy-mono(ethylacetoacetato)zirconium, tri-n-propoxy-mono(ethylacetoacetato)zirconium, tri-i-propoxy-mono(ethylacetoacetato)zirconium, tri-n-butoxy-mono(ethylacetoacetato)zirconium, tri-sec-butoxy-mono(ethylacetoacetato)zirconium, tri-t-butoxy-mono(ethylacetoacetato)zirconium, diethoxy-bis(ethylacetoacetato)zirconium, di-n-propoxy-bis(ethylacetoacetato)zirconium, di-i-propoxy-bis(ethylacetoacetato)zirconium, di-n-butoxy-bis(ethylacetoacetato)zirconium, di-sec-butoxy-bis(ethylacetoacetato)zirconium, di-t-butoxy-bis(ethylacetoacetato)zirconium, monoethoxytris(ethylacetoacetato)zirconium, mono-n-propoxy-tris(ethylacetoacetato)zirconium, mono-i-propoxy-tris(ethylacetoacetato)zirconium, mono-n-butoxy-tris(ethylacetoacetato)zirconium, mono-sec-butoxy-tris(ethylacetoacetato)zirconium, mono-t-butoxy-tris(ethylacetoacetato)zirconium, tetrakis(ethylacetoacetato)zirconium, mono(acetylacetonato)tris(ethylacetoacetato)zirconium, bis(acetylacetonato)bis(ethylacetoacetato)zirconium, and tris(acetylacetonato)mono(ethylacetoacetato)zirconium; and aluminum chelate compounds, such as tris(acetylacetonato)aluminum and tris(ethylacetoacetato)aluminum

Examples of the organic acid serving as a hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid serving as a hydrolysis catalyst include, but are not limited to, hydrochloric acid, nitric acid, sulfuric acid, hydrofluoric acid, and phosphoric acid.

Examples of the organic base serving as a hydrolysis catalyst include, but are not limited to pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base serving as a hydrolysis catalyst include, but are not limited to, ammonia, sodium hydroxide, potassium hydroxide, barium hydroxide, and calcium hydroxide.

Among these catalysts, a metal chelate compound, an organic acid, or an inorganic acid is preferred. These may be used alone or in combination of two or more species.

In particular, nitric acid is preferably used as a hydrolysis catalyst in the present invention.

The hydrolysis may involve the use of an organic solvent. Specific examples of the organic solvent include, but are not limited to, aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and trimethylbenzene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether, propylene glycol monoethyl ether, propylene glycol monopropyl ether, propylene glycol monobutyl ether, propylene glycol monomethyl ether acetate, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methylpyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents may be used alone or in combination of two or more species.

Of these, preferred are ketone solvents, such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone, in view of the preservation stability of the resultant solution.

After completion of the hydrolysis reaction, the reaction solution is used as is, or diluted or concentrated. The resultant reaction solution can be neutralized or treated with an ion-exchange resin, to thereby remove the hydrolysis catalyst (e.g., acid or base) used for the hydrolysis. Before or after such a treatment, alcohols (i.e., by-products), water, the hydrolysis catalyst used, etc. can be removed from the reaction solution through, for example, distillation under reduced pressure.

The thus-obtained hydrolysis condensate (polysiloxane) is in the form of a polysiloxane varnish dissolved in an organic solvent. This can be used as the below-described film-forming composition without any treatment. The resultant polysiloxane varnish may be subjected to solvent replacement, or may be appropriately diluted with a solvent. The organic solvent may be distilled off from the polysiloxane varnish to achieve a solid content concentration of 100%, so long as the preservation stability of the resultant varnish is not impaired.

The organic solvent used for, for example, the solvent replacement or dilution of the polysiloxane varnish may be identical to or different from the organic solvent used for the hydrolysis reaction of the hydrolyzable silane compound. No particular limitation is imposed on the solvent for the dilution, and a single solvent or two or more solvents may be arbitrarily selected and used.

[Film-Forming Composition]

The film-forming composition of the present invention contains the aforementioned hydrolyzable silane compound, a hydrolysate of the compound, and/or a hydrolysis condensate of the compound (polysiloxane), and a solvent.

The solid content concentration of the film-forming composition may be, for example, 0.1% by mass to 50% by mass, 0.1% by mass to 30% by mass, 0.1% by mass to 25% by mass, or 0.5% by mass to 20.0% by mass, relative to the entire mass of the composition. As described above, the term “solid content” refers to all components (except for the solvent component) contained in the composition.

The total amount of the hydrolyzable silane compound, the hydrolysate of the compound, and the hydrolysis condensate of the compound in the solid content is 20% by mass or more. From the viewpoint of achieving the aforementioned effects of the present invention with high reproducibility, the total amount may be, for example, 50% by mass to 100% by mass, 60% by mass to 100% by mass, 70% by mass to 100% by mass, 80% by mass to 100% by mass, or 80% by mass to 99% by mass.

The total concentration of the hydrolyzable silane compound, the hydrolysate of the compound, and the hydrolysis condensate of the compound in the composition may be, for example, 0.5% by mass to 20.0% by mass.

The film-forming composition can be produced by mixing of the aforementioned hydrolyzable silane compound, a hydrolysate of the compound, and/or a hydrolysis condensate of the compound, a solvent, and an optionally used additional component (if incorporated). In this case, a solution containing the hydrolysis condensate, etc. may be previously prepared, and the solution may be mixed with a solvent or an additional component.

No particular limitation is imposed on the order of mixing of these components. For example, a solvent may be added to and mixed with a solution containing the hydrolysis condensate, etc., and an additional component may be added to the resultant mixture. Alternatively, a solution containing the hydrolysis condensate, etc., a solvent, and an additional component may be mixed simultaneously.

If necessary, an additional solvent may be fmally added, or some components that can be relatively easily dissolved in a solvent may be finally added without being incorporated into the mixture. However, from the viewpoint of preventing aggregation or separation of components to prepare a highly homogeneous composition with high reproducibility, the composition is preferably prepared from a previously prepared solution containing the well-dissolved hydrolysis condensate, etc. It should be noted that the hydrolysis condensate, etc. may be aggregated or precipitated when mixed with a solvent or an additional component, depending on, for example, the type or amount of the solvent or the amount or nature of the component. It should also be noted that when a composition is prepared from a solution containing the hydrolysis condensate, etc., the concentration of the solution of the hydrolysis condensate, etc. or the amount of the solution used must be determined so as to achieve a desired amount of the hydrolysis condensate, etc. contained in the finally produced composition.

During preparation of the composition, the composition may be appropriately heated so long as the components are not decomposed or denatured.

In the present invention, the film-forming composition may be filtered with, for example, a submicrometer-order filter during production of the composition or after mixing of all the components.

The film-forming composition of the present invention can be suitably used as a resist underlayer film-forming composition for a lithographic process (in particular, an EUV lithographic process).

[Solvent]

No particular limitation is imposed on the solvent used in the film-forming composition of the present invention, so long as the solvent can dissolve the aforementioned solid content.

No limitation is imposed on such a solvent, so long as the solvent can dissolve the aforementioned hydrolyzable silane compound, a hydrolysate or hydrolysis condensate of the compound, or an additional component.

Specific examples of the solvent include methylcellosolve acetate, ethylcellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol mooethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, methyl 3-methoxy-2-methylpropionate, methyl 2-hydroxy-3-methybutyrate, ethyl methoxyacetate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and y-butyrolactone. These solvents may be used alone or in combination of two or more species.

The film-forming composition of the present invention may contain water as a solvent. When water is contained as a solvent, the amount of water is, for example, 30% by mass or less, preferably 20% by mass or less, more preferably 15% by mass or less, relative to the total mass of the solvents contained in the composition.

[Additional Additive]

The film-forming composition of the present invention may contain various additives in accordance with the intended use of the composition.

Examples of the additives include known additives incorporated in a material (composition) for forming a film (e.g., a resist underlayer film, an anti-reflective coating, or a pattern reversing film) that can be used in the production of a semiconductor device, such as a crosslinking agent, a crosslinking catalyst, a stabilizer (e.g., an organic acid, water, or an alcohol), an organic polymer compound, an acid generator, a surfactant (e.g., a nonionic surfactant, an anionic surfactant, a cationic surfactant, a silicon-containing surfactant, a fluorine-containing surfactant, or an UV curable surfactant), a pH adjuster, a rheology controlling agent, and an adhesion aid.

In the film-forming composition of the present invention, each of the hydrolyzable silane compound, a hydrolysate of the compound, and a hydrolysis condensate of the compound has a catalytic function. Thus, the composition exhibits excellent curability without addition of a generally used curing catalyst. However, the composition may contain a curing catalyst (e.g., an ammonium salt, a phosphine compound, a phosphonium salt, a sulfonium salt, or a nitrogen-containing silane compound), so long as the effects of the present invention are not impaired.

Examples of the additives include, but are not limited to, those described below.

<Crosslinking Catalyst>

The aforementioned crosslinking catalyst may be added as a catalyst for promoting the crosslinking reaction. Specific examples of the crosslinking catalyst include benzyltriethylammonium chloride. A single crosslinking catalyst may be used, or two or more crosslinking catalysts may be used in combination. In the case of addition of the aforementioned crosslinking catalyst, the amount of the crosslinking catalyst added is generally 0.1% by mass to 5.0% by mass, relative to the total mass of the hydrolyzable silane compound, a hydrolysate of the compound, and a hydrolysis condensate of the compound.

<Stabilizer>

The aforementioned stabilizer may be added for the purpose of, for example, stabilization of a hydrolysis condensate of the aforementioned hydrolyzable silane compound. Specifically, an organic acid, water, an alcohol, or any combination of these may be added.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Of these, oxalic acid or maleic acid is preferred. In the case of addition of an organic acid, the amount of the organic acid added may be 0.1% by mass to 5.0% by mass relative to the total mass of the hydrolyzable silane compound, a hydrolysate of the compound, and a hydrolysis condensate of the compound. Such an organic acid can also serve as a pH adjuster.

The aforementioned water may be, for example, pure water, ultrapure water, or ion-exchange water. In the case of use of water, the amount of water added may be 1 part by mass to 20 parts by mass relative to 100 parts by mass of the film-forming composition.

The aforementioned alcohol is preferably an alcohol that easily evaporates by heating after the application of the composition. Examples of the alcohol include methanol, ethanol, propanol, i-propanol, and butanol. In the case of addition of an alcohol, the amount of the alcohol added may be 1 part by mass to 20 parts by mass relative to 100 parts by mass of the film-forming composition.

<Organic Polymer>

Addition of the aforementioned organic polymer compound to the composition can control, for example, the dry etching rate (a decrease in film thickness per unit time) of a film (resist underlayer film) formed from the composition, attenuation coefficient, or refractive index. No particular limitation is imposed on the organic polymer compound, and the organic polymer compound is appropriately selected from among various organic polymers (polycondensation polymer and addition polymerization polymer) depending on the purpose of addition thereof.

Specific examples of the organic polymer compound include addition polymerization polymers and polycondensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer having an aromatic or heteroaromatic ring that functions as a light-absorbing moiety (e.g., a benzene ring, a naphthalene ring, an anthracene ring, a triazine ring, a quinoline ring, or a quinoxaline ring) can also be suitably used in the case where such a function is required. Specific examples of such an organic polymer compound include, but are not limited to, addition polymerization polymers containing, as structural units, addition polymerizable monomers (e.g., benzyl acrylate, benzyl methacrylate, phenyl acrylate, naphthyl acrylate, anthryl methacrylate, anthrylmethyl methacrylate, styrene, hydroxystyrene, benzyl vinyl ether, and N-phenylmaleimide); and polycondensation polymers such as phenol novolac and naphthol novolac.

When an addition polymerization polymer is used as an organic polymer compound, the polymer compound may be a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylate ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyltriethoxysilane, and glycidyl acrylate.

Specific examples of the methacrylate ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinylacetic acid, vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as a polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride.

Examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer compound contains a hydroxy group, the hydroxy group can be crosslinked with, for example, a hydrolysis condensate.

Generally, the organic polymer compound may have a weight average molecular weight of 1,000 to 1,000,000. In the case of incorporation of the organic polymer compound, the weight average molecular weight may be, for example, 3,000 to 300,000, or 5,000 to 300,000, or 10,000 to 200,000, from the viewpoints of sufficiently achieving the functional effect of the polymer and preventing the precipitation of the polymer in the composition.

These organic polymer compounds may be used alone or in combination of two or more species.

When the film-forming composition of the present invention contains an organic polymer compound, the amount of the organic polymer compound cannot be univocally determined, since the amount should be appropriately determined in consideration of, for example, the function of the organic polymer compound. The amount of the organic polymer compound may be 1% by mass to 200% by mass relative to the total mass of the hydrolyzable silane compound, a hydrolysate of the compound, and a hydrolysis condensate of the compound. From the viewpoint of, for example, preventing the precipitation of the polymer compound in the composition, the amount may be, for example, 100% by mass or less, and is preferably 50% by mass or less, more preferably 30% by mass or less. From the viewpoint of, for example, sufficiently achieving the effect of the polymer compound, the amount may be, for example, 5% by mass or more, and is preferably 10% by mass or more, more preferably 30% by mass or more.

<Acid Generator>

Examples of the acid generator include a thermal acid generator and a photoacid generator. A photoacid generator is preferably used.

Examples of the photoacid generator include, but are not limited to, an onium salt compound, a sulfonimide compound, and a disulfonyldiazomethane compound.

Examples of the thermal acid generator include, but are not limited to, tetramethylammonium nitrate.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl)iodonium camphorsulfonate, and bis(4-t-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, triphenylsulfonium camphorsulfonate, and triphenylsulfonium chloride.

Specific examples of the sulfonimide compound include, but are not limited to, N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Specific examples of the disulfonyldiazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

When the film-forming composition of the present invention contains an acid generator, the amount of the acid generator cannot be univocally determined, since the amount should be appropriately determined in consideration of, for example, the type of the acid generator. The amount of the acid generator is generally 0.01% by mass to 5% by mass relative to the total mass of the hydrolyzable silane compound, a hydrolysate of the compound, and a hydrolysis condensate of the compound. From the viewpoint of, for example, preventing the precipitation of the acid generator in the composition, the amount is preferably 3% by mass or less, more preferably 1% by mass or less. From the viewpoint of, for example, sufficiently achieving the effect of the acid generator, the amount is preferably 0.1% by mass or more, more preferably 0.5% by mass or more.

These acid generators may be used alone or in combination of two or more species, and a photoacid generator and a thermal acid generator may be used in combination.

<Surfactant>

When the film-forming composition of the present invention is used as a resist underlayer film-forming composition for lithography, a surfactant particularly effectively prevents formation of, for example, pinholes and striations during application of the composition to a substrate. Examples of the surfactant include a nonionic surfactant, an anionic surfactant, a cationic surfactant, a silicon-containing surfactant, a fluorine-containing surfactant, and an UV curable surfactant. Specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as trade names EFTOP EF301, EF303, and EF352 (available from Mitsubishi Materials Electronic Chemicals Co., Ltd. (former Tohkem Products Corporation)), trade names MEGAFACE F171, F173, R-08, R-30, R-30N, and R-40LM (available from DIC Corporation), Fluorad FC430 and FC431 (available from Sumitomo 3M Limited), trade name Asahi Guard AG710 and trade names SURFLON S-382, SC101, SC102, SC103, SC104, SC105, and SC106 (available from AGC Inc.); and Organosiloxane Polymer KP341 (available from Shin-Etsu Chemical Co., Ltd.).

These surfactants may be used alone or in combination of two or more species.

When the film-forming composition of the present invention contains a surfactant, the amount of the surfactant may be 0.0001% by mass to 5% by mass, or 0.01% by mass to 1% by mass, or 0.01% by mass to 1% by mass, relative to the total mass of the hydrolyzable silane compound, a hydrolysate of the compound, and a hydrolysis condensate of the compound.

<Rheology Controlling Agent>

The aforementioned rheology controlling agent is added mainly for the purpose of improving the fluidity of the film-forming composition, and particularly for the purpose of improving the uniformity of the thickness of a film formed in a baking process or improving the fillability of the composition in the interior of a hole. Specific examples of the rheology controlling agent include phthalic acid derivatives, such as dimethyl phthalate, diethyl phthalate, di-i-butyl phthalate, dihexyl phthalate, and butyl-i-decyl phthalate; adipic acid derivatives, such as di-normal butyl adipate, di-i-butyl adipate, di-i-octyl adipate, and octyldecyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

In the case of use of such a rheology controlling agent, the amount of the rheology controlling agent added is generally less than 30% by mass relative to the amount of the entire solid content of the film-forming composition.

<Adhesion Aid>

The aforementioned adhesion aid is added mainly for the purpose of improving the adhesion between a substrate or a resist and a film (resist underlayer film) formed from the film-forming composition, and particularly for the purpose of preventing removal of the resist during development. Specific examples of the adhesion aid include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, dimethylvinylethoxysilane, diphenyldimethoxysilane, and phenyltriethoxysilane; silazanes, such as hexamethyldisilazane, N,N′-bis(trimethylsilyl)urea, dimethyltrimethylsilylamine, and trimethylsilylimidazole; silanes, such as vinyltrichlorosilane, γ-chloropropyltrimethoxysilane, y-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea.

In the case of use of such an adhesion aid, the amount of the adhesion aid added is generally less than 5% by mass, preferably less than 2% by mass, relative to the amount of the entire solid content of the film-forming composition.

<pH Adjuster>

The pH adjuster that may be added in the composition is, for example, an acid having one or more carboxylic groups (e.g., any organic acid exemplified above in the section <Stabilizer>), bisphenol S, or a bisphenol S derivative. The amount of bisphenol S or a bisphenol S derivative is 0.01 parts by mass to 20 parts by mass, or 0.01 parts by mass to 10 parts by mass, or 0.01 parts by mass to 5 parts by mass, relative to 100 parts by mass of the total mass of the hydrolyzable silane compound, a hydrolysate of the compound, and a hydrolysis condensate of the compound.

Specific examples of the bisphenol S and the bisphenol S derivative include, but are not limited to, those described below.

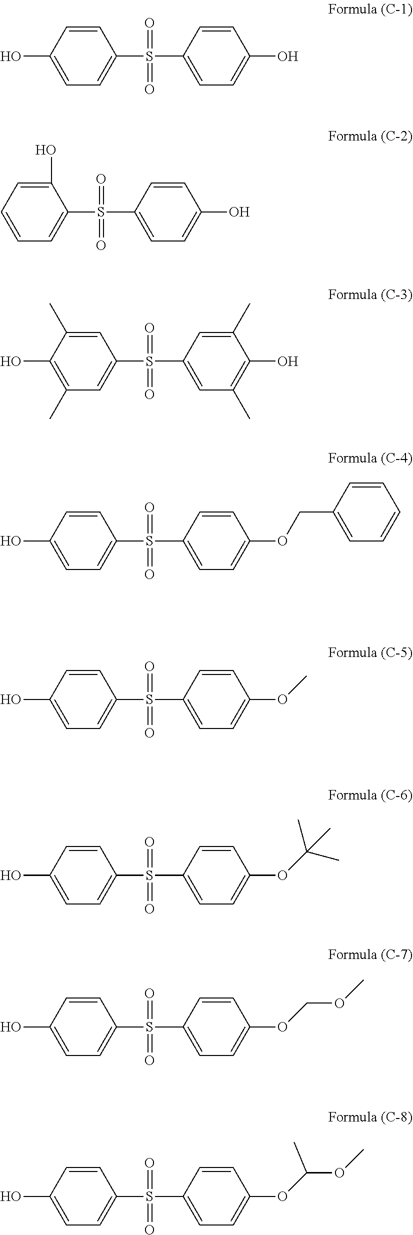

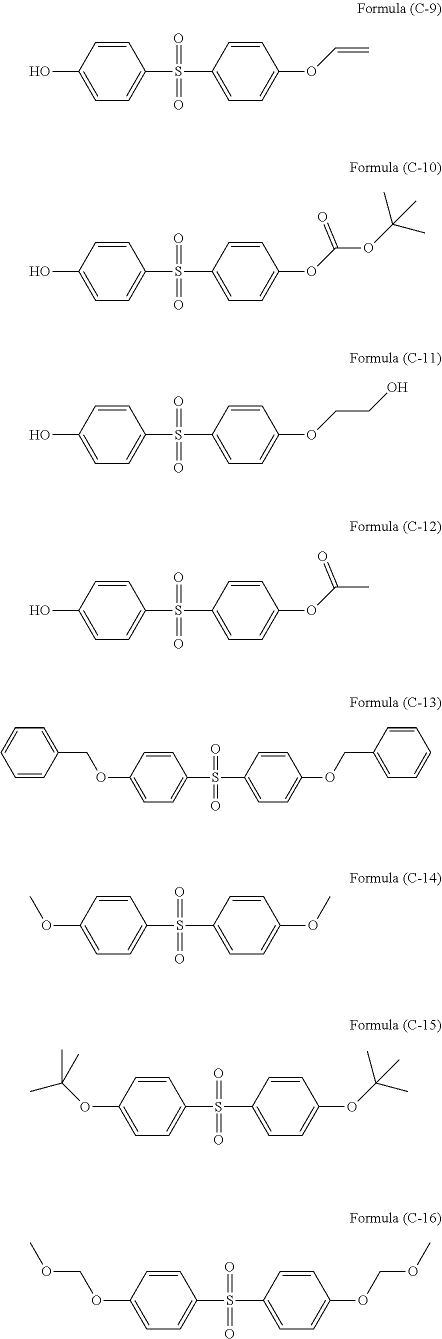

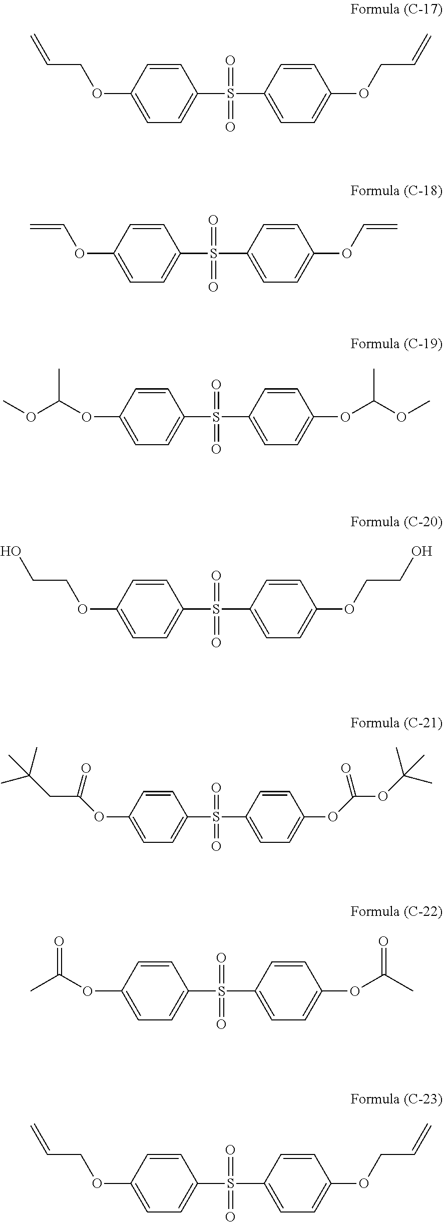

[Production Method for Semiconductor Device]

Next will be described a production method for a semiconductor device (i.e., one embodiment of the present invention) by using the aforementioned film-forming composition as a resist underlayer film-forming composition. The present invention is also directed to a resist underlayer film formed from the composition, and the production method for a semiconductor device.

Firstly, the resist underlayer film-forming composition (the film-forming composition of the present invention) is applied onto a substrate used for the production of a semiconductor device (e.g., a silicon wafer substrate, a silicon/silicon dioxide-coated substrate, a silicon nitride substrate, a glass substrate, an ITO substrate, a polyimide substrate, or a substrate coated with a low dielectric constant material (low-k material)) by an appropriate application method with, for example, a spinner or a coater, followed by baking of the composition, to thereby form a resist underlayer film.

The baking is performed under appropriately determined conditions; i.e., a baking temperature of 40° C. to 400° C. or 80° C. to 250° C. and a baking time of 0.3 minutes to 60 minutes. Preferably, the baking temperature is 150° C. to 250° C., and the baking time is 0.5 minutes to 2 minutes.

The thus-formed resist underlayer film has a thickness of, for example, 10 nm to 1,000 nm, or 20 nm to 500 nm, or 50 nm to 300 nm, or 100 nm to 200 nm, or 10 nm to 100 nm.

In another embodiment, an organic underlayer film can be formed on the aforementioned substrate, and then the aforementioned resist underlayer film can be formed on the organic underlayer film. No particular limitation is imposed on the organic underlayer film used in the embodiment, and the organic underlayer film may be arbitrarily selected from among those conventionally used in a lithographic process.

When the organic underlayer film is formed on the substrate, the resist underlayer film is formed on the organic underlayer film, and the below-described resist film is formed on the resist underlayer film, the pattern width of the photoresist can be narrowed. Thus, even when the photoresist is applied thinly for preventing pattern collapse, the substrate can be processed through selection of an appropriate etching gas described below. For example, the resist underlayer film of the present invention can be processed by using, as an etching gas, a fluorine-containing gas that achieves a significantly high etching rate for the photoresist. The organic underlayer film can be processed by using, as an etching gas, an oxygen-containing gas that achieves a significantly high etching rate for the resist underlayer film of the present invention. The substrate can be processed by using, as an etching gas, a fluorine-containing gas that achieves a significantly high etching rate for the organic underlayer film.

Subsequently, for example, a photoresist layer (resist film) is formed on the resist underlayer film of the present invention. The resist film can be formed by a well-known method; i.e., application of a resist composition (i.e., photoresist) onto the resist underlayer film, and baking of the composition.

The resist film has a thickness of, for example, 10 nm to 10,000 nm, or 100 nm to 2,000 nm, or 200 nm to 1,000 nm, or 30 nm to 200 nm.

No particular limitation is imposed on the photoresist used for the resist film formed on the resist underlayer film, so long as the photoresist is sensitive to light used for exposure. The photoresist may be either of negative and positive photoresists. Examples of the photoresist include a positive photoresist formed of a novolac resin and a 1,2-naphthoquinone diazide sulfonic acid ester; a chemically amplified photoresist formed of a binder having a group that decomposes with an acid to thereby increase the alkali dissolution rate and a photoacid generator; a chemically amplified photoresist formed of a low-molecular-weight compound that decomposes with an acid to thereby increase the alkali dissolution rate of the photoresist, an alkali-soluble binder, and a photoacid generator; and a chemically amplified photoresist formed of a binder having a group that decomposes with an acid to thereby increase the alkali dissolution rate, a low-molecular-weight compound that decomposes with an acid to thereby increase the alkali dissolution rate of the photoresist, and a photoacid generator.

Specific examples of commercially available products include, but are not limited to, trade name APEX-E, available from Shipley, trade name PAR710, available from Sumitomo Chemical Company, Limited, and trade name SEPR430, available from Shin-Etsu Chemical Co., Ltd. Other examples include fluorine atom-containing polymer-based photoresists described, for example, in Proc. SPIE, Vol. 3999, 330-334 (2000), Proc. SPIE, Vol. 3999, 357-364 (2000), and Proc. SPIE, Vol. 3999, 365-374 (2000).

Subsequently, light exposure is performed through a predetermined mask. The light exposure may involve the use of, for example, a KrF excimer laser (wavelength: 248 nm), an ArF excimer laser (wavelength: 193 nm), and an F2 excimer laser (wavelength: 157 nm).

After the light exposure, post exposure bake may optionally be performed. The post exposure bake is performed under appropriately determined conditions; i.e., a heating temperature of 70° C. to 150° C. and a heating time of 0.3 minutes to 10 minutes.

For the resist film formed on the resist underlayer film, the photoresist may be replaced with a resist for electron beam lithography (hereinafter may be referred to as “electron beam resist”) or a resist for EUV lithography (hereinafter may be referred to as “EUV resist”).

The electron beam resist may be either of negative and positive resists. Specific examples of the electron beam resist include a chemically amplified resist formed of an acid generator and a binder having a group that decomposes with an acid to thereby change the alkali dissolution rate; a chemically amplified resist formed of an alkali-soluble binder, an acid generator, and a low-molecular-weight compound that decomposes with an acid to thereby change the alkali dissolution rate of the resist; a chemically amplified resist formed of an acid generator, a binder having a group that decomposes with an acid to thereby change the alkali dissolution rate, and a low-molecular-weight compound that decomposes with an acid to thereby change the alkali dissolution rate of the resist; a non-chemically amplified resist formed of a binder having a group that decomposes with electron beams to thereby change the alkali dissolution rate; and a non-chemically amplified resist formed of a binder having a moiety that is cut with electron beams to thereby change the alkali dissolution rate. Also in the case of use of such an electron beam resist, a resist pattern can be formed by using electron beams as an irradiation source in the same manner as in the case of using the photoresist.

The EUV resist may be a methacrylate resin-based resist.

Subsequently, development is performed with a developer. When, for example, a positive photoresist is used, an exposed portion of the photoresist is removed to thereby form a resist pattern.

Examples of the developer include alkaline aqueous solutions (alkaline developers), for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine.

The developer may be an organic solvent. When, for example, a positive photoresist is used, an exposed portion of the photoresist is removed to thereby form a pattern of the photoresist.

Specific examples of the organic solvent that may be used as a developer include, but are not limited to, methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate.

The developer may optionally contain, for example, a surfactant. The development is performed under appropriately determined conditions; i.e., a temperature of 5° C. to 50° C. and a time of 10 seconds to 600 seconds.

Thus-formed pattern of the resist film (upper layer) is used as a protective film for removing the resist underlayer film (intermediate layer). The resist underlayer film is removed through dry etching, and the dry etching can be performed with any of gases, such as tetrafluoromethane (CF₄), perfluorocyclobutane (CF₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

The dry etching of the resist underlayer film is preferably performed with a halogen-containing gas. In general, a resist film (photoresist) formed of an organic substance is hard to be removed by dry etching with a halogen-containing gas. In contrast, the resist underlayer film of the present invention, which contains numerous silicon atoms, is quickly removed by dry etching with a halogen-containing gas. Therefore, a reduction in the thickness of the photoresist in association with the dry etching of the resist underlayer film can be suppressed. Thus, the photoresist can be used in the form of thin film. Therefore, the dry etching of the resist underlayer film is preferably performed with a fluorine-containing gas. Examples of the fluorine-containing gas include, but are not limited to, tetrafluoromethane (CF₄), perfluorocyclobutane (CF₄F₈), perfluoropropane (C₃F₈), trifluoromethane, and difluoromethane (CH₂F₂).

Subsequently, the patterned resist film (upper layer) and the patterned resist underlayer film (intermediate layer) are used as protective films for removing the organic underlayer film (lower layer). The organic underlayer film is preferably removed by dry etching with an oxygen-containing gas, since the resist underlayer film of the present invention, which contains numerous silicon atoms, is less likely to be removed by dry etching with an oxygen-containing gas.

Finally, the semiconductor substrate is processed by using the patterned resist film (upper layer), the patterned resist underlayer film (intermediate layer), and the patterned organic underlayer film (lower layer) as protective films. The processing of the semiconductor substrate is preferably performed by dry etching with a fluorine-containing gas.

Examples of the fluorine-containing gas include tetrafluoromethane (CF₄), perfluorocyclobutane (CF₄F₈), perfluoropropane (C₃F₈), trifluoromethane, and difluoromethane (CH₂F₂).

An organic anti-reflective coating may be formed on the resist underlayer film before formation of the resist film. No particular limitation is imposed on the composition used for formation of the anti-reflective coating, and, for example, the composition may be appropriately selected from anti-reflective coating compositions that have been conventionally used in a lithographic process. The anti-reflective coating can be formed by a commonly used method, for example, application of the composition with a spinner or a coater, and baking of the composition.

The substrate to which the resist underlayer film-forming composition (composed of the film-forming composition of the present invention) is applied may have an organic or inorganic anti-reflective coating formed thereon by, for example, a CVD process. The resist underlayer film of the present invention may be formed on the anti-reflective coating.

The resist underlayer film of the present invention may absorb light used in a lithographic process depending on the wavelength of the light. In such a case, the resist underlayer film can function as an anti-reflective coating having the effect of preventing reflection of light from the substrate.

Furthermore, the resist underlayer film of the present invention can be used as, for example, a layer for preventing the interaction between the substrate and the resist film (e.g., photoresist); a layer having the function of preventing the adverse effect, on the substrate, of a material used for the resist film or a substance generated during the exposure of the resist film to light; a layer having the function of preventing diffusion of a substance generated from the substrate during heating and baking to the resist film serving as an upper layer; and a barrier layer for reducing a poisoning effect of a dielectric layer of the semiconductor substrate on the resist film.

The aforementioned resist underlayer film can be applied to a substrate having via holes for use in a dual damascene process, and can be used as an embedding material to fill up the holes. The resist underlayer film can also be used as a planarization material for planarizing the surface of a semiconductor substrate having irregularities.

The aforementioned resist underlayer film can function as an EUV resist underlayer film or a hard mask. Also, the resist underlayer film can be used as an anti-reflective EUV resist underlayer coating capable of, without intermixing with an EUV resist, preventing the reflection, from a substrate or an interface, of exposure light undesirable for EUV exposure (wavelength: 13.5 nm); for example, UV (ultraviolet) light or DUV (deep ultraviolet) light (ArF light, KrF light). Thus, the reflection can be efficiently prevented in the underlayer of the EUV resist. When the resist underlayer film is used as an EUV resist underlayer film, the film can be processed in the same manner as in the photoresist underlayer film.

### EXAMPLES

The present invention will next be described in more detail with reference to Synthesis Examples and Examples, but the present invention should not be construed as being limited to the following Examples.

[1] Synthesis of Polymer (Hydrolysis Condensate)

### Synthesis Example 1

A 300-mL flask was charged with 25.6 g of tetraethoxysilane, 7.82 g of methyltriethoxysilane, 1.91 g of cyanoethyltriethoxysilane, and 53.0 g of acetone. While the resultant mixture was stirred with a magnetic stirrer, 11.7 g of 0.01 M aqueous nitric acid solution was added dropwise to the flask.

After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E1)) was found to have a weight average molecular weight Mw of 1,500 as determined by GPC in terms of polystyrene.

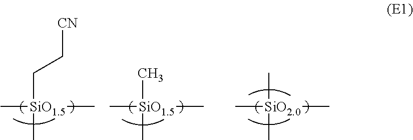

### Synthesis Example 2

A 300-mL flask was charged with 24.5 g of tetraethoxysilane, 11.0 g of cyanoethyltriethoxysilane, and 53.3 g of acetone. While the resultant mixture was stirred with a magnetic stirrer, 11.2 g of 0.01 M aqueous nitric acid solution was added dropwise to the flask.

After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E2)) was found to have a weight average molecular weight Mw of 1,300 as determined by GPC in terms of polystyrene.

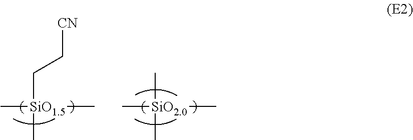

### Synthesis Example 3

A 300-mL flask was charged with 25.2 g of tetraethoxysilane, 7.71 g of methyltriethoxysilane, 2.45 g of 5-(triethoxysilyl)bicyclo(2,2,1)heptyl-2-carbonitrile, and 53.1 g of acetone. While the resultant mixture was stirred with a magnetic stirrer, 11.5 g of 0.01 M aqueous nitric acid solution was added dropwise to the flask.

After completion of the dropwise addition, the flask was transferred to an oil bath set at 85° C., and the mixture was refluxed for 240 minutes. Thereafter, 70 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E3)) was found to have a weight average molecular weight Mw of 1,700 as determined by GPC in terms of polystyrene.

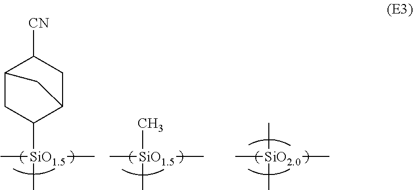

### Synthesis Example 4

A 300-mL flask was charged with 22.7 g of tetraethoxysilane, 13.2 g of 5-(triethoxysilyl)bicyclo(2,2,1)heptyl-2-carbonitrile, and 53.8 g of acetone. While the resultant mixture was stirred with a magnetic stirrer, 10.4 g of 0.01 M aqueous nitric acid solution was added dropwise to the flask.

After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E4)) was found to have a weight average molecular weight Mw of 1,200 as determined by GPC in terms of polystyrene.

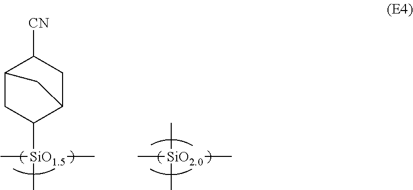

### Synthesis Example 5

A 300-mL flask was charged with 24.0 g of tetraethoxysilane, 5.87 g of methyltriethoxysilane, 2.33 g of 5-(triethoxysilyl)bicyclo(2,2,1)heptyl-2-carbonitrile, 3.40 g of triethoxysilylpropyldiallyl isocyanurate, and 53.4 g of acetone. While the resultant mixture was stirred with a magnetic stirrer, 11.0 g of 0.01 M aqueous nitric acid solution was added dropwise to the flask.

After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E5)) was found to have a weight average molecular weight Mw of 1,500 as determined by GPC in terms of polystyrene.

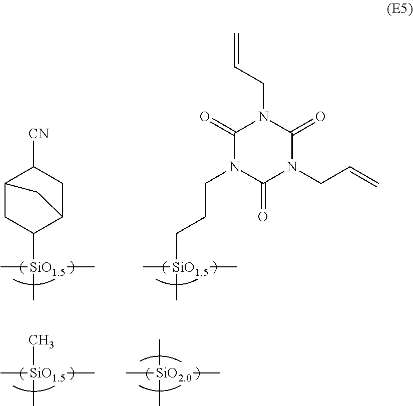

### Synthesis Example 6

A 300-mL flask was charged with 24.8 g of tetraethoxysilane, 6.07 g of methyltriethoxysilane, 2.41 g of 5-(triethoxysilyl)bicyclo(2,2,1)heptyl-2-carbonitrile, 2.18 g of bicyclo(2,2,1)heptenyltriethoxysilane, and 53.2 g of acetone. While the resultant mixture was stirred with a magnetic stirrer, 11.3 g of 0.01 M aqueous nitric acid solution was added dropwise to the flask.

After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E6)) was found to have a weight average molecular weight Mw of 1,500 as determined by GPC in terms of polystyrene.

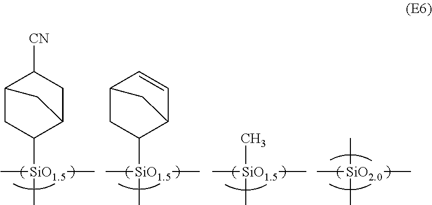

### Synthesis Example 7

A 300-mL flask was charged with 24.3 g of tetraethoxysilane, 5.95 g of methyltriethoxysilane, 2.37 g of 5-(triethoxysilyl)bicyclo(2,2,1)heptyl-2-carbonitrile, 2.89 g of benzenesulfonamidepropyltriethoxysilane, and 53.3 g of acetone. While the resultant mixture was stirred with a magnetic stirrer, 11.1 g of 0.01 M aqueous nitric acid solution was added dropwise to the flask.

After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E7)) was found to have a weight average molecular weight Mw of 1,800 as determined by GPC in terms of polystyrene.

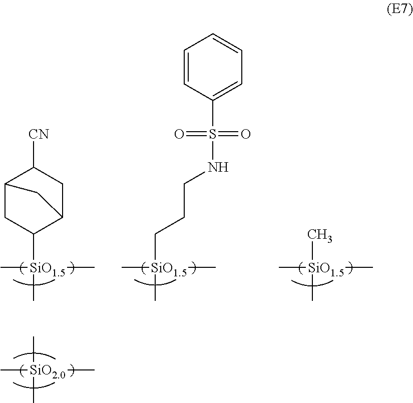

### Synthesis Example 8

A 300-mL flask was charged with 21.1 g of tetraethoxysilane, 6.19 g of methyltriethoxysilane, 2.05 g of 5-(triethoxysilyl)bicyclo(2,2,1)heptyl-2-carbonitrile, and 53.3 g of acetone. While the resultant mixture was stirred with a magnetic stirrer, a mixture of 26.1 g of 0.2 M aqueous nitric acid solution and 0.30 g of dimethylaminopropyltrimethoxysilane was added dropwise to the flask.

After completion of the dropwise addition, the flask was transferred to an oil bath set at 85° C., and the mixture was refluxed for 240 minutes. Thereafter, 60 g of propylene glycol monomethyl ether was added to the mixture, and then acetone, methanol and ethanol (i.e., reaction by-products), and water were distilled off under reduced pressure, followed by concentration, to thereby prepare an aqueous solution of a hydrolysis condensate (polymer).

Subsequently, propylene glycol monomethyl ether was added to the solution so as to achieve a solvent proportion of propylene glycol monomethyl ether of 100% and a solid residue content of 20% by mass at 140° C. The resultant polymer (corresponding to Formula (E8)) was found to have a weight average molecular weight Mw of 1,700 as determined by GPC in terms of polystyrene.

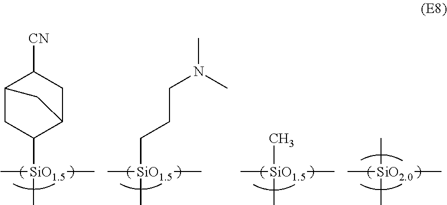

### Synthesis Example 9

A 300-mL flask was charged with 24.8 g of tetraethoxysilane, 6.08 g of methyltriethoxysilane, 4.49 g of 3-thiocyanatopropyltriethoxysilane, and 53.2 g of acetone. While the resultant mixture was stirred with a magnetic stirrer, 11.4 g of 0.01 M aqueous nitric acid solution was added dropwise to the flask.

After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E9)) was found to have a weight average molecular weight Mw of 1,800 as determined by GPC in terms of polystyrene.

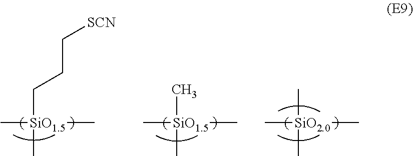

### Synthesis Example 10

A 300-mL flask was charged with 23.2 g of tetraethoxysilane, 12.6 g of 3-thiocyanatopropyltriethoxysilane, and 53.7 g of acetone. While the resultant mixture was stirred with a magnetic stirrer, 10.6 g of 0.01 M aqueous nitric acid solution was added dropwise to the flask.

After completion of the dropwise addition, the flask was transferred to an oil bath set at 85° C., and the mixture was refluxed for 240 minutes. Thereafter, 72 g of propylene glycol monomethyl ether acetate was added to the mixture, and then acetone, ethanol (i.e., reaction by-product), and water were distilled off under reduced pressure, followed by concentration, to thereby prepare an aqueous solution of a hydrolysis condensate (polymer).

Subsequently, propylene glycol monomethyl ether acetate was added to the solution so as to achieve a solvent proportion of propylene glycol monomethyl ether acetate of 100% and a solid residue content of 20% by mass at 140° C. The resultant polymer (corresponding to Formula (E10)) was found to have a weight average molecular weight Mw of 1,600 as determined by GPC in terms of polystyrene.

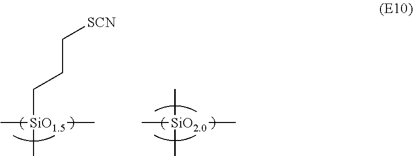

### Comparative Synthesis Example 1

A 300-mL flask was charged with 24.1 g of tetraethoxysilane, 1.8 g of phenyltrimethoxysilane, 9.5 g of methyltriethoxysilane, and 53.0 g of acetone. While the resultant mixture was stirred with a magnetic stirrer, 11.7 g of 0.01 M aqueous nitric acid solution was added dropwise to the mixture.

After completion of the dropwise addition, the flask was transferred to an oil bath set at 85° C., and the mixture was refluxed for 240 minutes. Thereafter, 70 g of propylene glycol monomethyl ether was added to the mixture, and then acetone, methanol and ethanol (i.e., reaction by-products), and water were distilled off under reduced pressure, followed by concentration, to thereby prepare an aqueous solution of a hydrolysis condensate (polymer).

Subsequently, propylene glycol monomethyl ether was added to the solution so as to achieve a solvent proportion of propylene glycol monomethyl ether of 100% and a solid residue content of 13% by mass at 140° C. The resultant polymer (corresponding to Formula (C1)) was found to have a weight average molecular weight Mw of 1,400 as determined by GPC in terms of polystyrene.

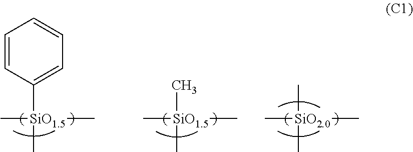

[2] Preparation of Composition to be Applied to Resist Pattern

Each of the polysiloxanes (polymers) prepared in the aforementioned Synthesis Examples, an additive, and a solvent were mixed in proportions shown in Table 1, and the resultant mixture was filtered with a fluororesin-made filter (0.1 μm), to thereby prepare a composition to be applied to a resist pattern. In Table 1, the amount of each component added is shown by part(s) by mass.

The amount of each polymer shown in Table 1 corresponds not to the amount of the polymer solution, but to the amount of the polymer itself.

In Table 1, DIW denotes ultrapure water; PGEE, propylene glycol monoethyl ether; PGMEA, propylene glycol monoethyl ether acetate; and PGME, propylene glycol monoethyl ether.

Furthermore, MA denotes maleic acid; TPSNO3, triphenylsulfonium nitrate; TPSTFA, triphenylsulfonium trifluoroacetate; TPSML, triphenylsulfonium maleate; TPSCl, triphenylsulfonium chloride; BTEAC, benzyltriethylammonium chloride; TMANO3, tetramethylammonium nitrate; and TPSCS, triphenylsulfonium camphorsulfonate.

TABLE 1

| | Polymer | Additive 1 | Additive 2 | Solvent | | | |
|---|---|---|---|---|---|---|---|
| Example 1 | Synthesis | MA | TPSNO3 | PGEE | PGMEA | PGME | DIW |
| | Example 1 | | | | | | |
| (part(s) by mass) | 1 | 0.03 | 0.05 | 40 | 10 | 38 | 12 |
| Example 2 | Synthesis | MA | TPSTFA | PGEE | PGMEA | PGME | DIW |
| | Example 2 | | | | | | |
| (part(s) by mass) | 1 | 0.03 | 0.05 | 40 | 10 | 38 | 12 |
| Example 3 | Synthesis | MA | TPSML | PGEE | PGMEA | PGME | DIW |
| | Example 3 | | | | | | |
| (part(s) by mass) | 1 | 0.03 | 0.05 | 40 | 10 | 38 | 12 |
| Example 4 | Synthesis | MA | TPSC1 | PGEE | PGMEA | PGME | DIW |
| | Example 4 | | | | | | |
| (part(s) by mass) | 1 | 0.03 | 0.05 | 40 | 10 | 38 | 12 |
| Example 5 | Synthesis | MA | BTEAC | PGEE | PGMEA | PGME | DIW |
| | Example 5 | | | | | | |
| (part(s) by mass) | 1 | 0.03 | 0.05 | 40 | 10 | 38 | 12 |
| Example 6 | Synthesis | MA | TMANO3 | PGEE | PGMEA | PGME | DIW |
| | Example 6 | | | | | | |
| (part(s) by mass) | 1 | 0.03 | 0.05 | 40 | 10 | 38 | 12 |
| Example 7 | Synthesis | MA | TPSNO3/ | PGEE | PGMEA | PGME | DIW |
| | Example 7 | | TPSCS | | | | |
| (part(s) by mass) | 1 | 0.03 | 0.05/0.05 | 40 | 10 | 38 | 12 |
| Example 8 | Synthesis | MA | | PGEE | PGMEA | PGME | DIW |
| | Example 8 | | | | | | |
| (part(s) by mass) | 1 | 0.03 | | 40 | 10 | 38 | 12 |
| Example 9 | Synthesis | MA | TPSNO3 | PGEE | PGMEA | PGME | DIW |
| | Example 9 | | | | | | |
| (part(s) by mass) | 1 | 0.03 | 0.05 | 40 | 10 | 38 | 12 |
| Example 10 | Synthesis | MA | TPSML | PGEE | PGMEA | PGME | DIW |
| | Example _10 | | | | | | |
| (part(s) by mass) | 1 | 0.03 | 0.05 | 40 | 10 | 38 | 12 |
| Comparative | Comparative | MA | | PGEE | PGMEA | PGME | DIW |
| Example 1 | Synthesis | | | | | | |
| | Example 1 | | | | | | |
| (part(s) by mass) | 1 | 0.03 | | 40 | 10 | 38 | 12 |
| Comparative | Comparative | MA | TPSNO3 | PGEE | PGMEA | PGME | DIW |
| Example 2 | Synthesis | | | | | | |
| | Example 1 | | | | | | |
| (part(s) by mass) | 1 | 0.03 | 0.05 | 40 | 10 | 38 | 12 |

[3] Preparation of Organic Resist Underlayer Film-Forming Composition

In a nitrogen atmosphere, a 100-mL four-necked flask was charged with 6.69 g (0.040 mol) of carbazole (available from Tokyo Chemical Industry Co., Ltd.), 7.28 g (0.040 mol) of 9-fluorenone (available from Tokyo Chemical Industry Co., Ltd.), and 0.76 g (0.0040 mol) of p-toluenesulfonic acid monohydrate (available from Tokyo Chemical Industry Co., Ltd.), and then 6.69 g of 1,4-dioxane (available from KANTO CHEMICAL CO., INC.) was added to the flask. The resultant mixture was stirred and heated to 100° C. for dissolution, to thereby initiate polymerization. After the elapse of 24 hours, the reaction mixture was left to cool to 60° C.

The cooled reaction mixture was then diluted with 34 g of chloroform (available from KANTO CHEMICAL CO., INC.), and the diluted mixture was added to 168 g of methanol (available from KANTO CHEMICAL CO., INC.) for precipitation.

The resultant precipitate was filtered, and the filtrate was dried with a reduced-pressure dryer at 80° C. for 24 hours, to thereby yield 9.37 g of a target polymer of Formula (X) (hereinafter abbreviated as “PCzFL”).

The results of ¹H-NMR analysis of PCzFL were as follows: ¹H-NMR (400 MHz, DMSO-d₆): δ7.03-7.55 (br, 12H), δ7.61-8.10 (br, 4H), δ11.18 (br, 1H).

PCzFL was found to have a weight average molecular weight Mw of 2,800 as determined by GPC in terms of polystyrene and a polydispersity Mw/Mn of 1.77.

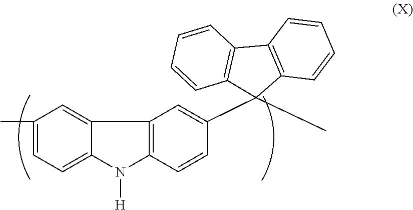

Subsequently, 20 g of PCzFL was mixed with 3.0 g of tetramethoxymethyl glycoluril (trade name: Powderlink 1174, available from Cytec Industries Japan (former Mitsui Cytec Ltd.)) serving as a crosslinking agent, 0.30 g of pyridinium p-toluenesulfonate serving as a catalyst, and 0.06 g of MEGAFACE R-30 (trade name, available from DIC Corporation) serving as a surfactant, and the mixture was dissolved in 88 g of propylene glycol monomethyl ether acetate. Thereafter, the resultant solution was filtered with a polyethylene-made microfilter (pore size: 0.10 μm), and then filtered with a polyethylene-made microfilter (pore size: 0.05 μm), to thereby prepare an organic resist underlayer film-forming composition used for a lithographic process using a multilayer film.

[4] Solvent Resistance Test and Developer Solubility Test

Each of the compositions prepared in Examples 1 to 10 and Comparative Examples 1 and 2 was applied onto a silicon wafer with a spinner, and then heated on a hot plate at 215° C. for one minute, to thereby form an Si-containing resist underlayer film. The thickness of the resultant underlayer film was measured.

Subsequently, a mixed solvent of propylene glycol monomethyl ether/propylene glycol monomethyl ether acetate (7/3 (V/V)) was applied onto the Si-containing resist underlayer film, and then spin-dried. The thickness of the underlayer film was measured after application of the mixed solvent, to thereby evaluate a change in film thickness between before and after application of the mixed solvent. Solvent resistance was evaluated as “Good” or “Not cured” when a change in film thickness after application of the mixed solvent was 1% or less or 1% or more, respectively, on the basis of the thickness before application of the mixed solvent.

Separately, an alkaline developer (2.38% aqueous TMAH solution) was applied onto an Si-containing resist underlayer film formed on a silicon wafer in the same manner as described above, and then spin-dried. The thickness of the underlayer film was measured after application of the developer, to thereby evaluate a change in film thickness between before and after application of the developer. Developer resistance was evaluated as “Good” or “Not cured” when a change in film thickness was 1% or less or 1% or more, respectively, on the basis of the thickness before application of the developer.

The results are shown in Table 2.

TABLE 2

| | Solvent resistance | Developer resistance |
|---|---|---|
| Example 1 | Good | Good |
| Example 2 | Good | Good |
| Example 3 | Good | Good |
| Example 4 | Good | Good |
| Example 5 | Good | Good |
| Example 6 | Good | Good |
| Example 7 | Good | Good |
| Example 8 | Good | Good |
| Example 9 | Good | Good |
| Example 10 | Good | Good |
| Comparative Example 1 | Not cured | Not cured |
| Comparative Example 2 | Good | Good |

[5] Measurement of Dry Etching Rate

The following etchers and etching gases were used for measurement of dry etching rate.

Lam2300 (available from Lam Research Co., Ltd.): CF₄/CHF₃/N₂ (fluorine-containing gas)

RIE-10NR (available from SAMCO Inc.): O₂ (oxygen-containing gas)

Each of the compositions prepared in Examples 1 to 10 and Comparative Example 2 was applied onto a silicon wafer with a spinner, and then heated on a hot plate at 215° C. for one minute, to thereby form an Si-containing resist underlayer film (thickness: 0.02 μm).

Similarly, the aforementioned organic resist underlayer film-forming composition was applied onto a silicon wafer with a spinner, and then heated on a hot plate at 215° C. for one minute, to thereby form an organic resist underlayer film (thickness: 0.20 μm).

The resultant silicon wafer provided with the Si-containing resist underlayer film was used for measurement of dry etching rate with CF₄/CHF₃/N₂ gas and O₂ gas as etching gases. Also, the silicon wafer provided with the organic resist underlayer film was used for measurement of dry etching rate with O₂ gas as an etching gas. The results are shown in Table 3.

The dry etching rate with O₂ gas was expressed as the ratio (resistance) relative to the dry etching rate of the organic resist underlayer film.

TABLE 3

| | Etching rate with | Oxygen-containing gas |
|---|---|---|
| | fluorine- | resistance |
| | containing gas | (relative to organic resist |
| | (nm/min) | underlayer film) |
| Example 1 | 35 | 0.02 |
| Example 2 | 40 | 0.03 |
| Example 3 | 33 | 0.02 |
| Example 4 | 38 | 0.03 |
| Example 5 | 38 | 0.02 |
| Example 6 | 35 | 0.02 |
| Example 7 | 37 | 0.02 |
| Example 8 | 39 | 0.02 |
| Example 9 | 40 | 0.02 |
| Example 10 | 45 | 0.03 |
| Comparative Example 2 | 30 | 0.02 |

[6] Formation of Resist Pattern by EUV Exposure: Negative Solvent Development

The aforementioned organic resist underlayer film-forming composition was applied onto a silicon wafer with a spinner, and then baked on a hot plate at 215° C. for 60 seconds, to thereby form an organic underlayer film (layer A) having a thickness of 90 nm.

The composition prepared in Example 1 was applied onto the organic underlayer film by spin coating, and then heated at 215° C. for one minute, to thereby form a resist underlayer film (layer B) (20 nm).

An EUV resist solution (methacrylate resin-based resist) was applied onto the resist underlayer film by spin coating, and then heated at 130° C. for one minute, to thereby form an EUV resist film (layer C). The EUV resist film was exposed to light with an EUV exposure apparatus (NXE3300B, available from ASML) under the following conditions: NA: 0.33, σ: 0.67/0.90, Dipole.

After the light exposure, post exposure bake (PEB, at 110° C. for one minute) was performed, and the resultant product was cooled on a cooling plate to room temperature, followed by development with an organic solvent developer (butyl acetate) for 60 seconds and rinsing treatment, to thereby form a resist pattern.

Each of the compositions prepared in Examples 2 to 10 and Comparative Example 2 was used, and a resist pattern was formed through the same procedure as described above.

Each of the thus-formed resist patterns was evaluated for formation of a 44 nm pitch and a 22 nm line-and-space by determining the pattern shape through observation of a cross section of the pattern.

In the observation of the pattern shape, evaluation “Good” was given to a shape between footing and undercut and a state of no significant residue in a space portion; evaluation “Collapse” was given to an unfavorable state of peeling and collapse of the resist pattern; and evaluation “Bridge” was given to an unfavorable state of contact between upper portions or lower portions of the resist pattern. The results are shown in Table 4.

TABLE 4

| | Pattern shape |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Comparative Example 2 | Collapse |

1. A film-forming composition comprising at least one selected from among a hydrolyzable silane compound, a hydrolysate of the compound, and a hydrolysis condensate of the compound, and a solvent, the film-forming composition being wherein:
the hydrolyzable silane compound contains a hydrolyzable silane having a cyano group in the molecule and being of the following Formula (1):
R¹ₐR²_{b}Si(R³)_{4-(a+b)} (1)
(wherein R¹ is a group bonded to a silicon atom and is an organic group containing a cyano group;
R² is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these;
R³ is a group or atom bonded to a silicon atom, and is each independently a hydroxy group, an alkoxy group, an aralkyloxy group, an acyloxy group, or a halogen atom;
a is an integer of 1;
b is an integer of 0 to 2; and
a+b is an integer of 1 to 3).

2. The film-forming composition according to claim 1, wherein the organic group containing a cyano group is an organic group prepared by substitution of one or more hydrogen atoms of an alkyl group selected from the group consisting of a chain alkyl group, a branched alkyl group, and a cyclic alkyl group with a cyano-containing group selected from among a cyano group (—CN) and a thiocyanato group (—S—CN).

3. The film-forming composition according to claim 1, wherein the composition comprises a hydrolysis condensate of the hydrolyzable silane compound.

4. The film-forming composition according to claim 1, wherein the hydrolyzable silane compound further contains at least one selected from among a hydrolyzable silane of the following Formula (2):
R⁴_{c}Si(R⁵)_{4-c} (2)
(wherein R⁴ is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these;
R⁵ is a group or atom bonded to a silicon atom, and is each independently an alkoxy group, an aralkyloxy group, an acyloxy group, or a halogen atom; and
c is an integer of 0 to 3), and a hydrolyzable silane of the following Formula (3):
[R⁶_{d}Si(R⁷)_{3-d}]₂Yₑ (3)
(wherein R⁶ is a group bonded to a silicon atom via an Si—C bond, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, or a sulfonyl group, or any combination of these;
R⁷ is a group or atom bonded to a silicon atom, and is each independently an alkoxy group, an aralkyloxy group, an acyloxy group, or a halogen atom;
Y is a group bonded to a silicon atom via an Si—C bond, and is each independently an alkylene group or an arylene group;
d is an integer of 0 or 1; and
e is an integer of 0 or 1).

5. The film-forming composition according to claim 1, wherein the hydrolysis condensate is a hydrolysis condensate of the hydrolyzable silane compound containing a hydrolyzable silane having a cyano group in the molecule and being of Formula (1) in an amount of 0.1% by mole to 10% by mole relative to the entire amount of the hydrolyzable silane compound.

6. The film-forming composition according to claim 1, wherein hydrolysis of the hydrolyzable silane compound is performed with nitric acid serving as a hydrolysis catalyst.

7. The film-forming composition according to claim 1, wherein the solvent contains water.

8. The film-forming composition according to claim 1, wherein the composition further comprises a pH adjuster.

9. The film-forming composition according to claim 1, wherein the composition further comprises a surfactant.

10. The film-forming composition according to claim 1, wherein the composition is for forming a resist underlayer film for EUV lithography.

11. A resist underlayer film formed from the film-forming composition according to claim 1.

12. A semiconductor processing substrate comprising a semiconductor substrate and the resist underlayer film according to claim 11.
